(19) United States
(12) Patent Application Publication
(10) Pub. No.: US 2026/0033330 A1
(43) Pub. Date: Jan. 29, 2026

(54) SEMICONDUCTOR PACKAGE

(71) Applicant: SAMSUNG ELECTRONICS CO., LTD., Suwon-si (KR)

(72) Inventors: Eun Hye LEE, Suwon-si (KR); Dong Ok KWAK, Suwon-si (KR); Keun Young LEE, Suwon-si (KR); Tae-Young LEE, Suwon-si (KR); Ki-Hong JEONG, Suwon-si (KR)

(21) Appl. No.: 19/217,355

(22) Filed: May 23, 2025

(30) Foreign Application Priority Data
Jul. 24, 2024 (KR) 10-2024-0097786

(51) Int. Cl. H01L 23/367; H01L 23/00; H01L 23/31; H01L 23/373

(52) U.S. Cl. CPC H01L 23/367; H01L 23/3107; H01L 23/373; H01L 24/06; H01L 24/48; H01L 2224/06135; H01L 2224/06519; H01L 2224/48227

(57) ABSTRACT

A semiconductor package includes a substrate including a first surface and a second surface, and a first substrate pad on the second surface, a first semiconductor chip on the second surface and including a third surface and a fourth surface, a first hotspot within the first semiconductor chip, and a first chip pad on the fourth surface, a first dummy pad on the fourth surface, a first layer connecting the first hotspot and the first dummy pad, a first pillar on the first dummy pad, a mold film on the substrate and including a fifth surface and a sixth surface, a thermal interface material layer on the mold film, and a heat slug on the thermal interface material layer; the mold film includes a first recess recessed inwardly from the sixth surface of the mold film, and at least part of the thermal interface material layer is in the recess.

### CROSS-REFERENCE TO RELATED APPLICATION

This application claims priority under 35 U.S.C. 119 from Korean Patent Application No. 10-2024-0097786, filed on Jul. 24, 2024 in the Korean Intellectual Property Office, the contents of which are herein incorporated by reference in their entirety.

### FIELD

The present disclosure relates to a semiconductor package.

### BACKGROUND

As high-performance semiconductor chips are developed, high-temperature regions, such as charge pumps, are generated within the semiconductor chips. When the temperature of the semiconductor chips rises, the power is reduced to control the temperature. However, this process is one of the factors that weakens the performance of the semiconductor chips. Accordingly, research is underway on how to improve the heat dissipation characteristics of semiconductor packages without weakening the performance of the semiconductor chips.

### SUMMARY

Aspects of the present disclosure provide a semiconductor package with improved heat dissipation characteristics.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor package including a substrate including a first surface and a second surface that are opposite to each other in a first direction, and a first substrate pad on the second surface, a first semiconductor chip on the second surface and including a third surface facing the second surface, a fourth surface opposite to the third surface in the first direction, a first hotspot defined in a predetermined region within the first semiconductor chip, and a first chip pad on the fourth surface, a first wire connecting the first substrate pad and the first chip pad, a first dummy pad on the fourth surface and spaced apart from the first hotspot, a first layer connecting the first hotspot and the first dummy pad, a first pillar on the first dummy pad and extending in the first direction, a mold film on the substrate, covering at least part of the first semiconductor chip, at least part of the first pillar, and at least part of the first wire, and including a fifth surface facing the second surface and a sixth surface opposite to the fifth surface in the first direction, a thermal interface material layer on the mold film, and a heat slug on the thermal interface material layer, wherein the mold film includes a first recess recessed inwardly from the sixth surface of the mold film, and at least part of the thermal interface material layer fills a first space defined between an area of the sixth surface of the mold film where the first recess is formed and an interface of the first recess where the mold film and the first pillar are in contact.

According to an aspect of the present disclosure, there is provided a semiconductor package including a substrate including a first surface and a second surface that are opposite to each other in a first direction, and a first substrate pad on the second surface, a first semiconductor chip on the second surface and including a third surface facing the second surface, a fourth surface opposite to the third surface in the first direction, a first hotspot defined in a predetermined region within the first semiconductor chip, and a first chip pad on the fourth surface, a first wire connecting the first substrate pad and the first chip pad, a first dummy pad on the fourth surface and spaced apart from the first hotspot, a first layer connecting the first hotspot and the first dummy pad, a first pillar on the first dummy pad and extending in the first direction, a mold film on the substrate, covering at least part of the first semiconductor chip, at least part of the first pillar, and at least part of the first wire, and including a fifth surface facing the second surface and a sixth surface opposite to the fifth surface in the first direction, a thermal interface material layer on the mold film, and a heat slug on the thermal interface material layer, wherein the thermal interface material layer includes a first material layer and a second material layer disposed at a lower level in the first direction than the first material layer, the first material layer includes a seventh surface facing or corresponding to the sixth surface and an eighth surface opposite to the seventh surface in the first direction, and the second material layer includes a first interface in contact with the mold film and the first pillar and a second interface in contact with the seventh surface of the first material layer.

According to an aspect of the present disclosure, there is provided a semiconductor package including a substrate including a first surface and a second surface that are opposite to each other in a first direction, and a substrate pad on the second surface, a first semiconductor chip on the second surface and including a third surface facing the second surface, a fourth surface opposite to the third surface in the first direction, a first hotspot defined in a predetermined region within the first semiconductor chip, and a first chip pad on the fourth surface, a first upper dummy pad on the fourth surface and spaced apart from the first hotspot, a first layer connecting the first hotspot and the first upper dummy pad, a first upper pillar on the first upper dummy pad and extending in the first direction, at least one second semiconductor chip on the fourth surface, the at least one second semiconductor chip including a fifth surface facing the fourth surface, a sixth surface opposite to the fifth surface in the first direction, a second hotspot defined in a predetermined region within the at least one second semiconductor chip, and a second chip pad on the sixth surface, a second upper dummy pad on the sixth surface and spaced apart from the second hotspot, a second layer connecting the second hotspot and the second upper dummy pad, a second upper pillar on the second upper dummy pad and extending longitudinally in the first direction, a lower dummy pad on the fifth surface and spaced apart from the second hotspot, a third layer connecting the second hotspot and the lower dummy pad, a lower pillar connected to the lower dummy pad and extending in the first direction to be connected to the substrate, a mold film on the substrate, covering at least part of the first semiconductor chip, the at least one second semiconductor chip, the first and second upper pillars, and the lower pillar, and including a seventh surface facing the second surface and an eighth surface opposite to the seventh surface in the first direction, a thermal interface material layer on the mold film; and a heat slug on the thermal interface material layer, wherein the mold film includes at least two recesses recessed inwardly from the seventh surface, and at least part of the thermal interface material layer fills a first space defined between an area of the seventh surface of the mold film where the first recess, which corresponds to the first upper pillar, is formed and an interface of the first recess where the mold film and the first upper pillar are in contact, and fills a second space defined between an area of the seventh surface of the mold film where the second recess, which corresponds to the second upper pillar, is formed and an interface of the second recess where the mold film and the second upper pillar are in contact.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is a diagram illustrating a semiconductor package according to some embodiments.

FIG. 2 is an enlarged view of a region I of FIG. 1.

FIG. 3 is a schematic diagram illustrating part of the semiconductor package of FIG. 1.

FIG. 4 is a diagram illustrating a semiconductor package according to some embodiments.

FIG. 5 is a diagram illustrating a semiconductor package according to some embodiments.

FIG. 6 is a diagram illustrating a semiconductor package according to some embodiments.

FIG. 7 is a diagram illustrating a semiconductor package according to some embodiments.

FIG. 8 is a diagram illustrating a semiconductor package according to some embodiments.

FIG. 9 is a diagram illustrating a semiconductor package according to some embodiments.

FIG. 10 is a diagram illustrating a semiconductor package according to some embodiments.

FIG. 11 is a diagram illustrating a semiconductor package according to some embodiments.

FIG. 12 is a diagram illustrating a semiconductor package according to some embodiments.

FIG. 13 is a schematic diagram illustrating part of the semiconductor package of FIG. 12.

FIG. 14 is a schematic diagram illustrating part of the semiconductor package of FIG. 12.

FIG. 15 is a diagram illustrating a semiconductor package according to some embodiments.

FIG. 16 is a schematic diagram illustrating part of the semiconductor package of FIG. 15.

FIGS. 17 and 18 are schematic diagrams illustrating part of the semiconductor package of FIG. 15.

FIG. 19 is a diagram illustrating a semiconductor package according to some embodiments.

FIG. 20 is a diagram illustrating a semiconductor package according to some embodiments.

FIG. 21 is a diagram illustrating a semiconductor package according to some embodiments.

FIG. 22 is a diagram illustrating a semiconductor package according to some embodiments.

FIG. 23 is a flowchart illustrating a method of manufacturing a semiconductor package according to some embodiments.

FIGS. 24 through 31 are diagrams illustrating the method of manufacturing a semiconductor package according to some embodiments.

### DETAILED DESCRIPTION

A semiconductor package according to some embodiments will hereinafter be described with reference to the accompanying drawings.

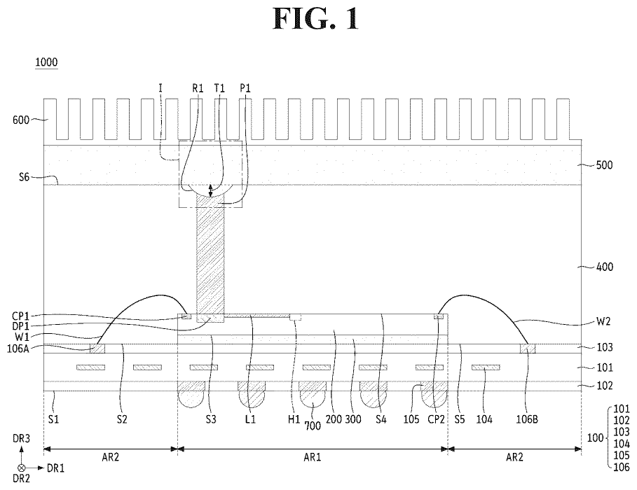

FIG. 1 is a diagram illustrating a semiconductor package according to some embodiments.

Referring to FIG. 1, a semiconductor package 1000 may include a substrate 100, a semiconductor chip 200, wires W1, wires W2, a dummy pad DP1, a layer L1, a pillar P1, a mold film 400, a thermal interface material layer 500, a heat slug 600, and connection terminals 700. In the following description, the term “upper part” (or “upper surface”) may be defined with reference to a third direction DR3, and the term “lower part” (or “lower surface”) may be defined with reference to the opposite direction of the third direction DR3. Additionally, a first direction DR1, a second direction DR2, and the third direction DR3 may be directions that intersect with one another. For example, the first, second, and third directions DR1, DR2, and DR3 may be perpendicular to one another.

The substrate 100 may have a surface S1 and a surface S2 that are opposite to each other in the third direction DR3. For example, the surface S1 may be the lower surface of the substrate 100, and the surface S2 may be the upper surface of the substrate 100. The substrate 100 may include a plate-shaped form. The substrate 100 may be a printed circuit board (PCB), but the present disclosure is not limited thereto.

When the substrate 100 is a PCB, the substrate 100 may be formed of at least one material selected from among a phenolic resin, an epoxy resin, or polyimide. The substrate 100 may include at least one material selected from among a tetrafunctional epoxy, polyphenylene ether, epoxy/polyphenylene oxide, bismaleimide triazine (BT), Thermount, cyanate ester, and a liquid crystal polymer. The substrate 100 may include a resin impregnated into a core material, such as glass fiber, glass cloth, or glass fabric, along with an inorganic filler. For example, the substrate 100 may include prepreg, Ajinomoto Build-up Film (ABF), FR-4, or BT.

The substrate 100 may include an insulating layer 101, a wiring layer 104, protective layers 102 and 103, substrate pads 105, and substrate pads 106.

The material of the insulating layer 101 may include silicon (Si). Additionally, the insulating layer 101 may also include a semiconductor element such as germanium (Ge), or a compound such as silicon carbide (SiC), gallium arsenide (GaAs), indium arsenide (InAs), or indium phosphide (InP). However, the material of the insulating layer 101 is not particularly limited.

The wiring layer 104 may be disposed within the insulating layer 101. The wiring layer 104 may be a conductive pattern electrically connected to the substrate pads 105 and the substrate pads 106. In FIG. 1, the wiring layer 104 is illustrated as extending only in the first direction DR1, but the wiring layer 104 may extend in both the first and third directions DR1 and DR3 to electrically connect the substrate pads 105 and the substrate pads 106. The wiring layer 104 may include a metal such as nickel (Ni), copper (Cu), gold (Au), silver (Ag), aluminum (Al), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), or ruthenium (Ru), or an alloy thereof.

The protective layer 102 may be formed on the surface S1 of the substrate 100. The protective layer 102 may be a lower passivation layer that protects the lower part of the substrate 100. The protective layer 102 may cover at least a portion of the lower surface of the insulating layer 101. The protective layer 102 may protect the lower surface of the insulating layer 101 and the wiring layer 104. In example embodiments, the protective layer 102 may include an insulating material such as an insulating polymer. Alternatively, the protective layer 102 may be formed as a multi-layer structure containing different materials, for example, silicon oxide (SiO₂) and silicon nitride (SiN).

The protective layer 103 may be formed on the surface S2 of the substrate 100. The protective layer 103 may be an upper passivation layer that protects the upper part of the substrate 100. The protective layer 103 may cover at least a portion of the upper surface of the insulating layer 101. The protective layer 103 may protect the upper surface of the insulating layer 101 and the wiring layer 104. In example embodiments, the protective layer 103 may include an insulating material such as an insulating polymer. Alternatively, the protective layer 103 may be formed as a multi-layer structure containing different materials, for example, SiO₂ and SiN.

The substrate pads 105 may be disposed on the surface S1 of the substrate 100. The substrate pads 105 may be exposed to the outside by the protective layer 102. For example, the sides of the substrate pads 105 may be covered by or surrounded by the protective layer 102, while the lower surfaces of the substrate pads 105 may be exposed by the protective layer 102. The lower surfaces of the substrate pads 105 may be coplanar with a lower surface of the protective layer 102. The substrate pads 105 may be electrically connected to the wiring layer 104. The substrate pads 105 may include a metal such as Ni, Cu, Au, Ag, Al, W, Ti, Ta, In, Mo, Mn, Co, Sn, Mg, Re, Be, Ga, or Ru, or an alloy thereof.

The connection terminals 700 may be attached to the lower surfaces of the substrate pads 105. At least some of the connection terminals 700 may be solder balls formed of a conductive material used to connect the semiconductor chip 200, which is included in the semiconductor package 1000, to an external device. For example, the connection terminals 700 may include a metal such as Ni, Cu, Au, Ag, Al, W, Ti, Ta, In, Mo, Mn, Co, Sn, Mg, Re, Be, Ga, or Ru, or an alloy thereof.

At least some of the connection terminals 700 may be configured not for electrical connection but for heat dissipation of the semiconductor package 1000. In this case, the surface S2 of the substrate 100 may be divided into a first area AR1 and a second area AR2. The first area AR1 may be a region on the surface S1 of the substrate 100 that vertically overlaps with the area where the connection terminals 700 for heat dissipation are disposed, and the second area AR2 may be a region on the surface S1 of the substrate 100 that surrounds the first area AR1 and does not vertically overlap with the area where the connection terminals 700 for heat dissipation are disposed.

Since the first area AR1 is adjacent to the connection terminals 700 for heat dissipation, heat dissipation characteristics can be improved by placing the semiconductor chip 200 on the first area AR1. Conversely, since the second area AR2 is physically farther from the connection terminals 700 for heat dissipation compared to the first area AR1, the heat dissipation characteristics may be lower when the semiconductor chip 200 is placed on the second area AR2 than when the semiconductor chip 200 is placed on the first area AR1.

The substrate pads 106 may be disposed on the surface S2 of the substrate 100. The substrate pads 106 may be exposed to the outside by the protective layer 103. For example, the sides of the substrate pads 106 may be covered by or surrounded by the protective layer 103, while the upper surfaces of the substrate pads 106 may be exposed by the protective layer 103. The upper surfaces of the substrate pads 106 may be coplanar with an upper surface of the protective layer 103. The substrate pads 106 may be electrically connected to the wiring layer 104. The substrate pads 106 may include a metal such as Ni, Cu, Au, Ag, Al, W, Ti, Ta, In, Mo, Mn, Co, Sn, Mg, Re, Be, Ga, or Ru, or an alloy thereof.

There may be multiple substrate pads 106. At least some of the substrate pads 106, i.e., substrate pads 106A, may be arranged at a distance (e.g., spaced apart) from the semiconductor chip 200 in the opposite direction of the first direction DR1. Additionally, at least some of the substrate pads 106, i.e., substrate pads 106B, may be arranged at a distance (e.g., spaced apart) from the semiconductor chip 200 in the first direction DR1. Multiple substrate pads 106A and multiple substrate pads 106B may be provided. The substrate pads 106A may be arranged side-by-side along the second direction DR2, and the substrate pads 106B may be arranged side-by-side along the second direction DR2.

As will be described below, the wires W1 electrically connected to the semiconductor chip 200 may be electrically connected to the upper surfaces of the substrate pads 106A, and the wires W2 electrically connected to the semiconductor chip 200 may be electrically connected to the upper surfaces of the substrate pads 106B. Accordingly, the substrate pads 106 may be electrically connected to the semiconductor chip 200.

The semiconductor chip 200 may have a surface S3 and a surface S4 that are opposite to each other in the third direction DR3. For example, the surface S3 may be the lower surface of the semiconductor chip 200, and the surface S4 may be the upper surface of the semiconductor chip 200. The substrate 100 may include a plate-shaped form. The semiconductor chip 200 may be disposed on the substrate 100 via a die attach film (DAF) 300. For example, in the state where the DAF 300 is applied to the surface S3 of the semiconductor chip 200, the semiconductor chip 200 may be mounted on the substrate 100 such that the surface S3 of the semiconductor chip 200 may face the surface S2 of the substrate 100.

The semiconductor chip 200 may be a non-volatile memory chip or a volatile memory chip, such as a phase change random access memory (PRAM), a resistive random access memory (RRAM), a magnetic random access memory (MRAM), a dynamic random access memory (DRAM), or a flash memory device, but the present disclosure is not limited thereto. Alternatively, the semiconductor chip 200 may be a logic chip.

The semiconductor chip 200 may include a hotspot H1. The hotspot H1 of the semiconductor chip 200 may be defined in a predetermined region within the semiconductor chip 200. The hotspot H1 is illustrated in FIG. 1 as being disposed near the surface S4 of the semiconductor chip 200, but the present disclosure is not limited thereto. For example, the hotspot H1 may be disposed at the center of the semiconductor chip 200, or near the surface S3 of the semiconductor chip 200. The hotspot H1 will hereinafter be described as being disposed near the surface S4, which corresponds to the upper surface of the semiconductor chip 200, as illustrated in FIG. 1.

The hotspot H1 may correspond to a region within the semiconductor chip 200 where components that generate relatively more heat are disposed. For example, the hotspot H1 may correspond to the region within the semiconductor chip 200 where components such as a charge pump, which generates a power source for the operation of the semiconductor chip 200, are located. To improve the heat dissipation characteristics of the semiconductor package 1000, it is crucial to effectively dissipate the heat generated at the hotspot H1.

Chip pads CP1 and chip pads CP2 may be disposed on the surface S4 of the semiconductor chip 200. The upper surfaces of the chip pads CP1 and the chip pads CP2 may be exposed to the outside. The chip pads CP1 and the chip pads CP2 may include a metal such as Ni, Cu, Au, Ag, Al, W, Ti, Ta, In, Mo, Mn, Co, Sn, Mg, Re, Be, Ga, or Ru, or an alloy thereof.

The chip pads CP1 may be disposed close to the edge of the semiconductor chip 200 in the direction opposite to the first direction DR1 so that they may be adjacent to the substrate pads 106A. The chip pads CP2 may be disposed close to the edge of the semiconductor chip 200 in the first direction DR1 so that they may be adjacent to substrate pads 106B. There may be multiple chip pads CP1 and multiple chip pads CP2. The chip pads CP1 may be arranged side-by-side along the second direction DR2, and the chip pads CP2 may be arranged side-by-side along the second direction DR2.

The wires W1 may electrically connect the substrate 100 and the semiconductor chip 200. Specifically, the wires W1 may electrically connect the substrate pads 106A of the substrate 100 with the chip pads CP1 of the semiconductor chip 200. First ends of the wires W1 may contact and be connected to the upper surfaces of the substrate pads 106A, while second (opposite) ends of the wires W1 may contact and be connected to the upper surfaces of the chip pads CP1.

The substrate pads 106A and the wires W1, as well as the chip pads CP1 and the wires W1, may be bonded through ball bonding, but the present disclosure is not limited thereto. Alternatively, in other embodiments, the substrate pads 106A and the wires W1, and/or the chip pads CP1 and the wires W1 may be bonded through stitch bonding.

The semiconductor package 1000 may receive at least one of the control signals, power signals, or ground signals necessary for the operation of the semiconductor chip 200 from an external device via the wires W1. Additionally, the semiconductor package 1000 may receive data signals to be stored in the semiconductor chip 200 from an external device via the wires W1, or transmit data stored in the semiconductor chip 200 to an external device via the wires W1.

The wires W1 may be connected by either thermo-compression bonding or ultrasonic bonding, or by a thermo-sonic bonding method that combines thermo-compression and ultrasonic bonding. The wires W1 may include at least one of Au, Ag, Cu, and Al.

The wires W2 may electrically connect the substrate 100 and the semiconductor chip 200. Specifically, the wires W2 may electrically connect the substrate pads 106B of the substrate 100 with the chip pads CP2 of the semiconductor chip 200. The same description provided for the wires W1 above is also applicable to the wires W2.

The dummy pad DP1 may be disposed on the surface S4 of the semiconductor chip 200. The upper surface of the dummy pad DP1 may be exposed to the outside. The dummy pad DP1 may include a metallic material, but unlike the chip pads CP1 and CP2, may not be intended to electrically connect the semiconductor chip 200 to other components. The dummy pad DP1 may serve as a thermal pathway to connect the hotspot H1 and the heat slug 600, facilitating the dissipation of heat from the hotspot H1 to the outside of the semiconductor package 1000. The dummy pad DP1 may be formed on the surface S4 of the semiconductor chip 200 during a wafer fabrication stage for manufacturing the semiconductor package 1000.

The layer L1 may connect the hotspot H1 and the dummy pad DP1. The layer L1 may include a metallic material such as a metal, but may not be intended to electrically connect the hotspot H1 and the dummy pad DP1. The layer L1 may be a layer designed to connect the hotspot H1 and the heat slug 600 as a thermal pathway to dissipate heat from the hotspot H1 to the outside of the semiconductor package 1000. The layer L1 may be referred to herein as a thermal pathway layer L1. The layer L1 may be formed within the semiconductor chip 200 during the wafer fabrication stage for manufacturing the semiconductor package 1000.

In FIG. 1, the layer L1 is illustrated as extending in the first direction DR1 along the surface S4 of the semiconductor chip 200, but the present disclosure is not limited thereto. For example, the shape of the layer L1 may vary depending on the location of the hotspot H1 within the semiconductor chip 200.

The pillar P1 may be disposed on the dummy pad DP1 and may extend longitudinally in the third direction DR3. The pillar P1 may include a metallic material such as Cu, but the present disclosure is not limited thereto. The pillar P1 may be connected to the hotspot H1 via the dummy pad DP1 and the layer L1, facilitating the efficient dissipation of heat generated at the hotspot H1 to the outside of the semiconductor package 1000. The thermal conductivity (or thermal transfer coefficient) of the material forming the pillar P1 may be higher than that of the mold film 400. As a result, when heat generated at the hotspot H1 is dissipated to the outside of the semiconductor package 1000 by convection, conduction, or radiation, the path through the layer L1, the dummy pad DP1, the pillar P1, the thermal interface material layer 500, and the heat slug 600 may facilitate more efficient heat dissipation.

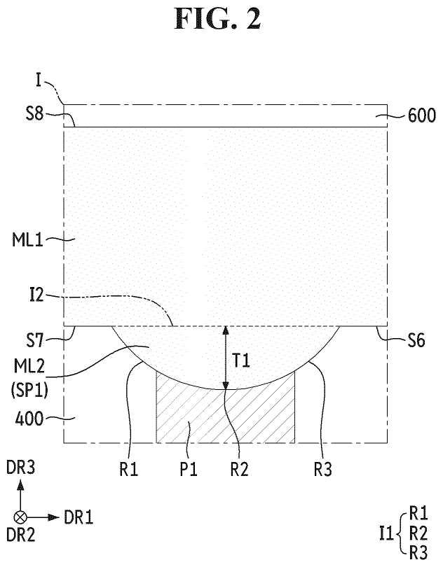

The lower surface of the pillar P1 may contact the upper surface of the dummy pad DP1, and the upper surface of the pillar P1 may contact the thermal interface material layer 500. As will be described below with reference to FIG. 2, the upper end of the pillar P1 may include a shape formed by drilling, and the upper surface of the drilled pillar P1 may be filled by the thermal interface material layer 500.

The mold film 400 may be disposed on the surface S2 of the substrate 100. The mold film 400 may include surfaces S5 and S6 that are opposite to each other in the third direction DR3. The surface S5, which is the lower surface of the mold film 400, may face the surface S2 of the substrate 100, and the surface S6, which is the upper surface of the mold film 400, may be opposite to or face away from the surface S2 of the substrate 100. The mold film 400 may cover or surround at least parts of the sides and upper surface of the semiconductor chip 200, at least parts of the sides of the pillar P1, at least parts of the wires W1 and at least parts of the wires W2, and at least part of the upper surface of the substrate 100. The mold film 400 may include an insulating resin such as prepreg, ABF, FR-4, BT, or Epoxy Molding Compound (EMC). The thermal transfer coefficient of the material forming the mold film 400 may be lower than that of the material constituting the pillar P1.

The thermal interface material layer 500 may be disposed on the mold film 400. The thermal interface material layer 500 may be formed of an adhesive, such as silica.

The heat slug 600 may indirectly contact the pillar P1 and the mold film 400 through the thermal interface material layer 500, receiving and dissipating the heat generated at the hotspot H1. Since the pillar P1 and the mold film 400 are indirectly connected to the heat slug 600 via the thermal interface material layer 500, without directly contacting the heat slug 600, heat can be effectively dissipated.

In FIG. 1, the semiconductor chip 200 is illustrated as being disposed on the first area AR1, which vertically overlaps with the area on the surface S2 of the substrate 100 where the connection terminals 700, which perform a heat dissipation function, are disposed, but the present disclosure is not limited thereto. Alternatively, for example, the semiconductor chip 200 may be disposed on the second area AR2, which does not vertically overlap with the area on the surface S2 of the substrate 100 where the connection terminals 700 are disposed. Since the heat from the hotspot H1 is dissipated through the layer L1, the dummy pad DP1, and the pillar P1 to the thermal interface material layer 500 and the heat slug 600, the placement of the semiconductor chip 200 on the substrate 100 may not be restricted.

FIG. 2 is an enlarged view of a region I of FIG. 1.

Referring to FIG. 2, the mold film 400 may include a recess R1 having a shape that is recessed inwardly from the surface S6 (i.e., in the opposite direction of the third direction DR3). The recess R1 may be upwardly concave. The recess R1 may be formed after placing the pillar P1 on the dummy pad DP1, shaping the mold film 400 to cover the pillar P1 and other components on the substrate 100, and then drilling the upper part of the pillar P1 and the upper part of the mold film 400 covering the pillar P1. Accordingly, when the thermal interface material layer 500 is formed on the mold film 400 after drilling, at least part of the thermal interface material layer 500 may fill the empty space created by the drilling. The thermal interface material layer 500 may be in or fill the recess R1.

For example, the thermal interface material layer 500 may include a material layer ML1 and a material layer ML2. The material layer MLI may be disposed on the surface S6 of the mold film 400, and the material layer ML2 may be disposed at a lower level in the third direction DR3 than material layer ML1. The material layer ML2 may fill a space SP1 between the area on the surface S6 of the mold film 400 where the recess R1 is formed and an interface I1 of the recess R1 where the material layer ML2 contacts the mold film 400 and the pillar P1.

The material layer ML1 may include a surface S7 that faces the surface S6 of the mold film 400 and a surface S8 that is opposite to the surface S7 in the third direction DR3. The heat slug 600 may be disposed on the surface S8 of the material layer ML1. The interface I1 of the recess R1 may include a first region R1, a second region R2, and a third region R3, which are sequentially arranged in the first direction DR1. The first and third regions R1 and R3 of the interface I1 may be the interfaces where the mold film 400 and the material layer ML2 contact each other. The second region R2 of the interface I1 may be the interface where the pillar P1 and the material layer ML2 contact each other.

The material layer ML2 may include two interfaces. An interface I1 of the material layer ML2 may be the same surface as the interface I1 of the recess R1. The interface I1 of the material layer ML2 may contact the mold film 400 and the pillar P1, while an interface I2 of the material layer ML2 may contact the surface S7 of the material layer ML1.

The width or thickness of the space SP1 (hereinafter referred to as the width or thickness of the recess R1), defined between the interface I1 of the recess R1, which contacts the mold film 400 and the pillar P1, and the area on the surface S6 of the mold film 400 where the recess R1 is formed, may be defined as a maximum length T1 in the third direction DR3 from the interface I2 of the material layer ML2 to the interface I1 of the material layer ML2.

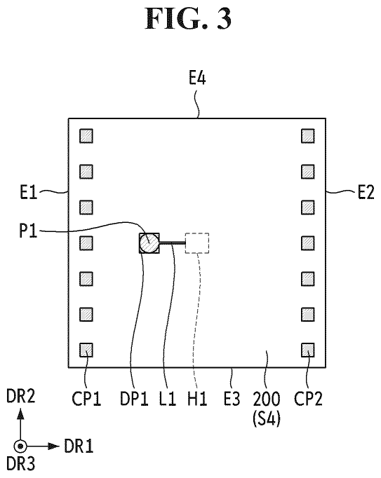

FIG. 3 is a schematic diagram illustrating part of the semiconductor package of FIG. 1.

Referring to FIG. 3, the surface S4 of the semiconductor chip 200 may include four edges E1, E2, E3, and E4. The edges E1 and E2 may each extend longitudinally in the second direction DR2 and may be spaced apart from each other in the first direction DR1. The edges E3 and E4 may each extend longitudinally in the first direction DR1 and may be spaced apart from each other in the second direction DR2. The chip pads CP1 may be arranged side-by-side along the edge E1, and the chip pads CP2 may be arranged side-by-side along the edge E2.

As illustrated in FIG. 3, when the hotspot H1 is disposed at the center of the semiconductor chip 200 rather than at the edge of the semiconductor chip 200, the dummy pad DP1 may be disposed on the surface S4 of the semiconductor chip 200 between the area where the chip pads CP1 are located and the area where the chip pads CP2 are located. In other words, the dummy pad DP1 may be disposed near the hotspot H1, rather than at the edge of the surface S4. Since the dummy pad DP1 and the pillar P1 on the dummy pad DP1 are disposed close to the hotspot H1, the heat dissipation characteristics of the semiconductor package 1000 can be improved.

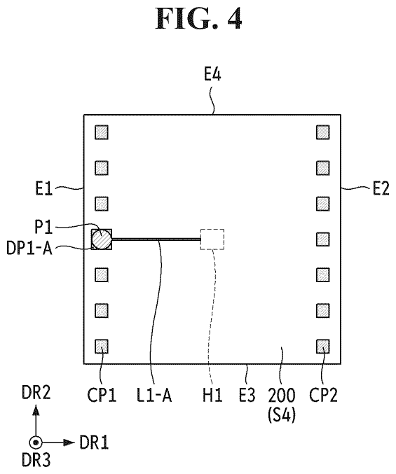

FIG. 4 is a diagram illustrating a semiconductor package according to some embodiments.

Referring to FIG. 4, contrary to what is illustrated in FIG. 3, a dummy pad DP1-A may be disposed between adjacent ones of the chip pads CP1 that are arranged side-by-side along an edge E1. A layer L1-A may connect a hotspot H1 and the dummy pad DP1-A. Since the dummy pad DP1-A and a pillar P1, which are designed to dissipate the heat generated at the hotspot H1 to the outside of a semiconductor package 1000, are disposed at the edge of a semiconductor chip 200, the central area of the semiconductor chip 200 can be efficiently utilized while effectively dissipating the heat generated at the hotspot H1.

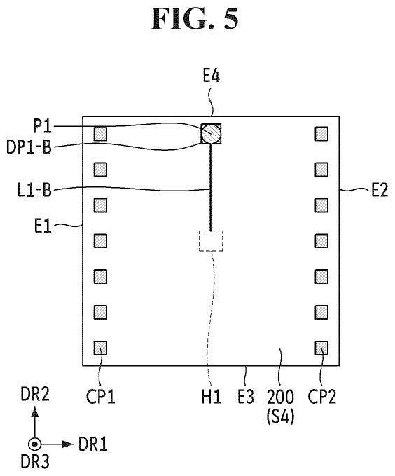

FIG. 5 is a diagram illustrating a semiconductor package according to some embodiments.

Referring to FIG. 5, contrary to what is illustrated in FIGS. 3 and 4, a dummy pad DP1-B may be disposed on or adjacent an edge E4 of a surface S4, which is not occupied by chip pads CP1 and chip pads CP2. A layer L1-B may connect a hotspot H1 and the dummy pad DP1-B. FIG. 5 illustrates the dummy pad DP1-B as being disposed on the edge E4, but alternatively, in some embodiments, the dummy pad DP1-B may be disposed on or adjacent an edge E3, which is also not occupied by the chip pads CP1 and the chip pads CP2. Since the dummy pad DP1-B and a pillar P1, which are designed to dissipate the heat generated at the hotspot H1 to the outside of the semiconductor package 1000, are disposed at the edge of a semiconductor chip 200, the central area of the semiconductor chip 200 can be efficiently utilized while effectively dissipating the heat generated at the hotspot H1.

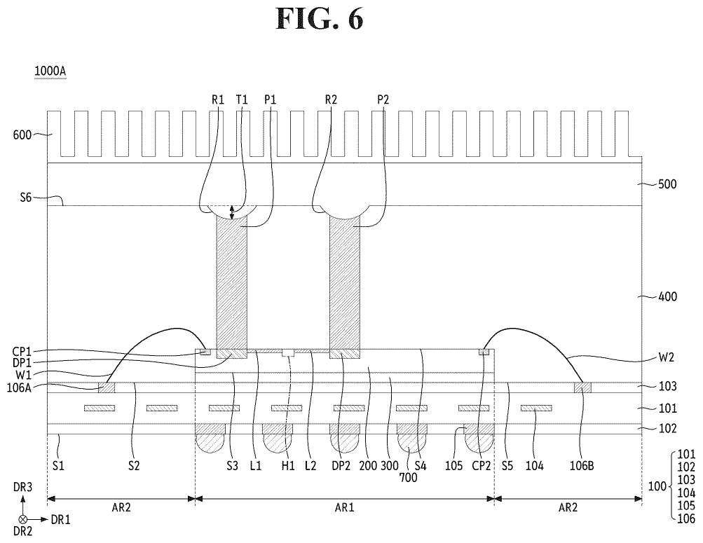

FIG. 6 is a diagram illustrating a semiconductor package according to some embodiments.

The embodiment of FIG. 6 will hereinafter be described, focusing mainly on the differences from the previous embodiments.

Referring to FIG. 6, a semiconductor package 1000A may further include a dummy pad DP2, a layer L2, a pillar P2, and a recess R2. The dummy pad DP2 may be connected to a hotspot H1 through the layer L2, and the pillar P2 may be disposed on the dummy pad DP2. The recess R2 may be formed by drilling the upper part of the pillar P2 and the upper part of a mold film 400 that covers the pillar P2, and may include a shape that is recessed inwardly from a surface S6 of the mold film 400. At least part of a thermal interface material layer 500 may fill the recess R2 formed by the drilling.

In this manner, by forming two or more conduction-based heat dissipation structures (e.g., layers, dummy pads, pillars, recesses, etc.) at the hotspot H1 defined in a predetermined region within a semiconductor chip 200, the heat generated at the hotspot H1 can be dissipated more effectively.

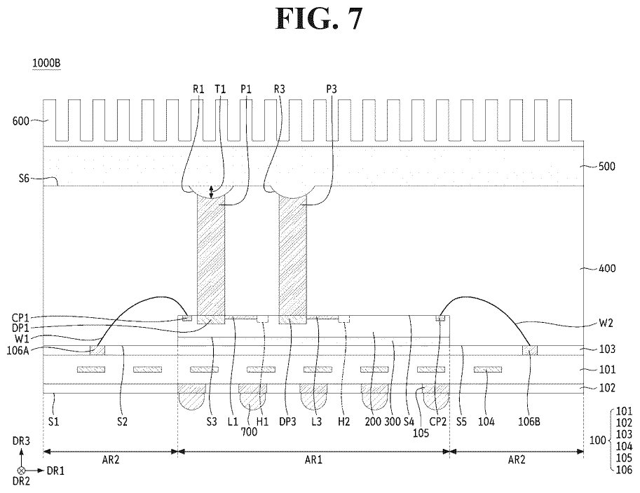

FIG. 7 is a diagram illustrating a semiconductor package according to some embodiments.

Referring to FIG. 7, a semiconductor package 1000B may further include a hotspot H2, a dummy pad DP3, a layer L3, a pillar P3, and a recess R3. The hotspot H2 is a region defined in a predetermined area within a semiconductor chip 200, and may be disposed spaced apart from a hotspot H1. The hotspot H2 may be connected to the dummy pad DP3, which is disposed on a surface S4 of the semiconductor chip 200, through the layer L3, and the pillar P3 may be disposed on the dummy pad DP3. The recess R3 may include a shape that is recessed inwardly from a surface S6 of a mold film 400, and at least part of a thermal interface material layer 500 may fill the recess R3.

The dummy pads DP1 and DP3 may each be disposed in the same direction relative to the hotspots H1 and H2. For example, the dummy pad DP1 may be disposed at a distance from the hotspot H1 in the opposite direction of a first direction DR1, and similarly, the dummy pad DP3 may also be disposed at a distance from the hotspot H2 in the opposite direction of the first direction DR1.

As the semiconductor chip 200 becomes more advanced, it may require multiple power sources. In this case, there may be two or more hotspots defined in the predetermined region within the semiconductor chip 200. To effectively dissipate the heat generated in the semiconductor chip 200, a conduction-based heat dissipation structure (e.g., layers, dummy pads, pillars, recesses, etc.) may be formed for each of the hotspots H1 and H2 within the semiconductor chip 200, allowing the heat generated at each of the hotspots H1 and H2 to be dissipated more effectively.

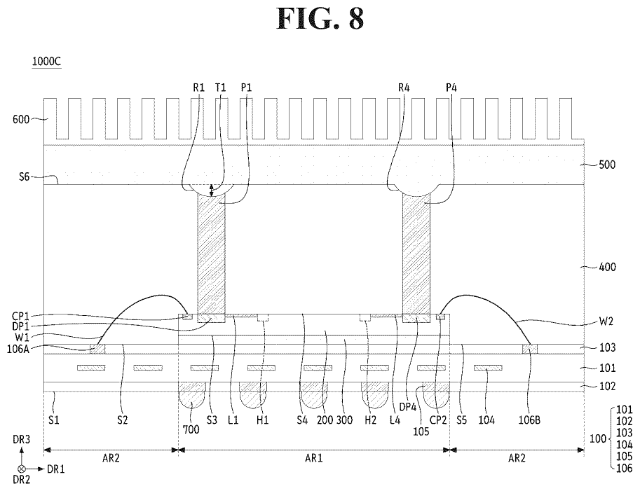

FIG. 8 is a diagram illustrating a semiconductor package according to some embodiments.

Referring to FIG. 8, a semiconductor package 1000C may further include a hotspot H2, a dummy pad DP4, a layer LA, a pillar P4, and a recess R4. The hotspot H2 may be connected to the dummy pad DP4, which is disposed on a surface S4 of a semiconductor chip 200, through the layer L4, and the pillar P4 may be disposed on the dummy pad DP4. The recess R4 may include a shape that is recessed inwardly from a surface S6 of a mold film 400, and at least part of a thermal interface material layer 500 may fill the recess R4.

A dummy pad DP1 and the dummy pad DP4 may be disposed in different directions relative to a hotspot H1 and the hotspot H2. For example, if the dummy pad DP1 is disposed at a distance from the hotspot H1 in the opposite direction of a first direction DR1, then the dummy pad DP4 may be disposed at a distance from the hotspot H2 in the first direction DR1. As a result, the dummy pad DP1 and a pillar P1 may be disposed close to an edge (“E1” in FIG. 2) of the surface S4, and the dummy pad DP4 and the pillar P4 may be disposed close to another edge (“E2” in FIG. 2) of the surface S4. Accordingly, since the dummy pads DP1 and DP4 and the pillars P1 and P4, which are designed to dissipate the heat generated at the hotspots H1 and H2 to the outside of the semiconductor package 1000C, are disposed at the edges of the semiconductor chip 200, the central area of the semiconductor chip 200 can be efficiently utilized while effectively dissipating the heat generated at the hotspots H1 and H2.

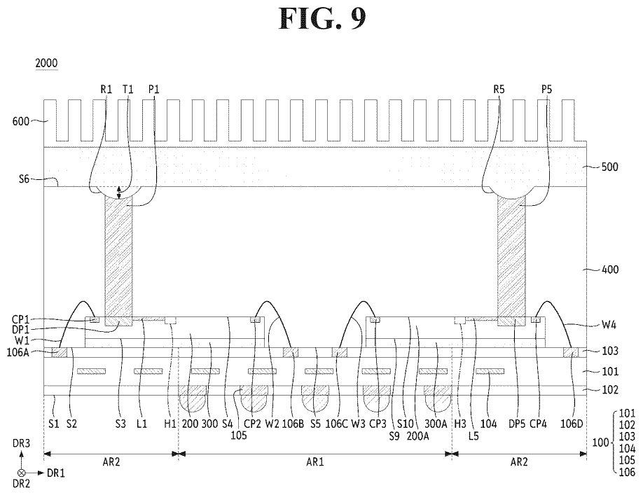

FIG. 9 is a diagram illustrating a semiconductor package according to some embodiments.

Referring to FIG. 9, a semiconductor package 2000 may further include substrate pads 106C, substrate pads 106D, a semiconductor chip 200A, a DAF 300A, chip pads CP3, chip pads CP4, wires W3, wires W4, a hotspot H3, a layer L5, a dummy pad DP5, a pillar P5, and a recess R5.

The substrate pads 106C and the substrate pads 106D may be disposed on a surface S2 of a substrate 100 and may be exposed by a protective layer 103. A plurality of substrate pads 106C and a plurality of substrate pads 106D may be provided. The substrate pads 106C may be arranged side-by-side in a second direction DR2, and the substrate pads 106D may be arranged side-by-side in the second direction DR2. The semiconductor chip 200A may include a surface S9 and a surface S10 that are opposite to each other in a third direction DR3. The semiconductor chip 200A may be disposed on the substrate 100 so that the surface S9 may face the surface S2 of the substrate 100. The semiconductor chip 200A may be mounted on the substrate 100 via the DAF 300A.

The chip pads CP3 and the chip pads CP4 may be disposed on the surface S10 of the semiconductor chip 200A. A plurality of chip pads CP3 and a plurality of chip pads CP4 may be provided. The chip pads CP3 may be arranged side-by-side in the second direction DR2, and the chip pads CP4 may be arranged side-by-side in the second direction DR2.

The semiconductor chip 200A may be a non-volatile memory chip or a volatile memory chip, such as a PRAM, an RRAM, an MRAM, a DRAM, or a flash memory device, but the present disclosure is not limited thereto. Alternatively, the semiconductor chip 200A may be a logic chip.

A plurality of wires W3 and a plurality of wires W4 may be provided. The wires W3 may electrically connect the substrate pads 106C and the chip pads CP3, and the wires W4 may electrically connect the substrate pads 106D and the chip pads CP4.

The hotspot H3 may be a region defined in a predetermined area within the semiconductor chip 200A. The heat generated at the hotspot H3 may be dissipated to the outside of the semiconductor package 2000 by convection, conduction, or radiation. The layer L5 may connect the hotspot H3 and the dummy pad DP5. The dummy pad DP5 may be disposed on the surface S10 of the semiconductor chip 200A at a distance from the hotspot H3, and the pillar P5 may be disposed on the dummy pad DP5. A surface S6 of a mold film 400 may include a recess R5 that is recessed inwardly into the mold film 400, and the interface of the recess R5 may contact the mold film 400 and the pillar P5.

When two or more semiconductor chips, i.e., a semiconductor chip 200 and the semiconductor chip 200A, are disposed at the same level on the substrate 100 to be spaced apart from each other, heat dissipation structures such as pillars may be formed for each of a hotspot H1 and the hotspot H3 within the semiconductor chips 200 and 200A, respectively. In this case, the pillars P1 and P5 may be disposed at the edges of the semiconductor package 2000. For example, the dummy pads DP1 and DP5 may be disposed in different directions relative to the hotspots H1 and H3 within the respective semiconductor chips. For example, if the dummy pad DP1 is disposed at a distance from the hotspot H1 in the opposite direction of a first direction DR1, then the dummy pad DP5 may be disposed at a distance from the hotspot H3 in the first direction DR1.

In this manner, since the pillars P1 and P5, which are designed to dissipate the heat generated in the semiconductor chips 200 and 200A, are disposed at the edges of the semiconductor package 2000, while the central area of the semiconductor package 2000 is filled with the mold film 400, the heat dissipation characteristics of the semiconductor package 2000 and the molding characteristics for protecting the semiconductor chips 200 and 200A can both be improved.

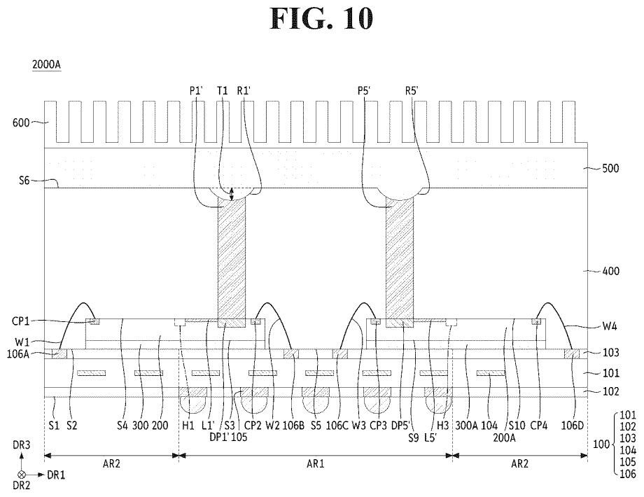

FIG. 10 is a diagram illustrating a semiconductor package according to some embodiments.

Referring to FIG. 10, a semiconductor package 2000A may include layers L1′ and L5′, dummy pads DP1′ and DP5′, pillars P1′ and P5′, and recesses R1′ and R5′. In the semiconductor package 2000A, the pillars P1′ and P5′ may be disposed at the center of the semiconductor package 2000A. For example, for semiconductor chips 200 and 200A, the dummy pads DP1′ and DP5′ may be disposed in different directions relative to hotspots H1 and H3. For example, if the dummy pad DP1′ is disposed at a distance from the hotspot H1 in a first direction DR1, then the dummy pad DP5′ may be disposed at a distance from the hotspot H3 in the opposite direction of the first direction DR1.

In this manner, since the pillars P1′ and P5′, which are designed to dissipate the heat generated in the semiconductor chips 200 and 200A, respectively, are disposed at the center of the semiconductor package 2000A, while the edges of the semiconductor package 2000A are filled with a mold film 400, the heat dissipation characteristics of the semiconductor package 2000A and the molding characteristics for protecting the semiconductor chips 200 and 200A can both be improved.

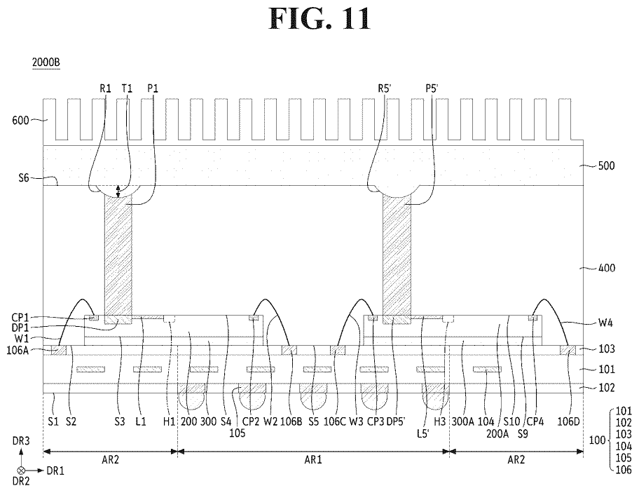

FIG. 11 is a diagram illustrating a semiconductor package according to some embodiments.

Referring to FIG. 11, in a semiconductor package 2000B, dummy pads DP1 and DP5′ may be disposed in the same direction relative to hotspots H1 and H3 for semiconductor chips 200 and 200A. For example, the dummy pad DP1 may be disposed at a distance from the hotspot H1 in the opposite direction of a first direction DR1, and similarly, the dummy pad DP5′ may also be disposed at a distance from the hotspot H3 in the opposite direction of the first direction DR1.

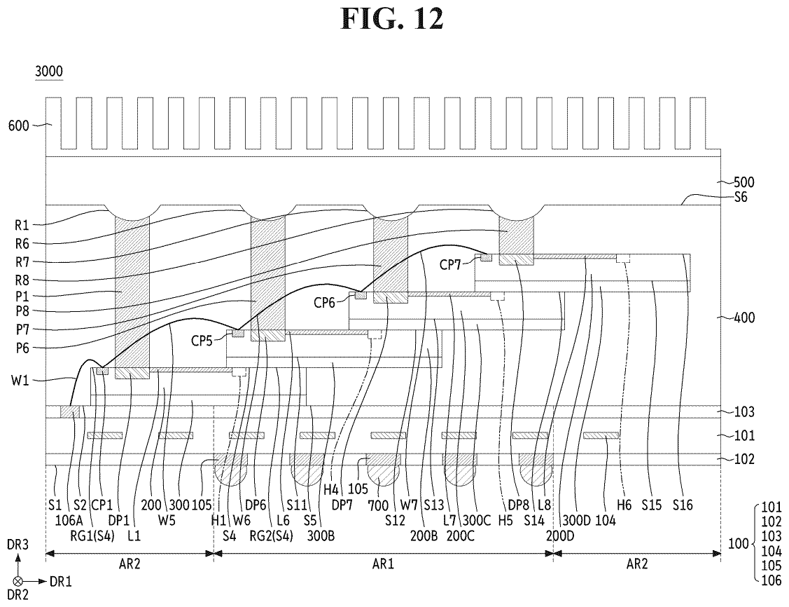

FIG. 12 is a diagram illustrating a semiconductor package according to some embodiments.

Referring to FIG. 12, a semiconductor package 3000 may include a substrate 100, semiconductor chips 200, 200B, 200C, and 200D, wires W1, wires W5, wires W6, wires W7, dummy pads DP1, DP6, DP7, and DP8, chip pads CP1, chip pads CP5, chip pads CP6, chip pads CP7, layers L1, L6, L7, and L8, pillars P1, P6, P7, and P8, a mold film 400, a thermal interface material layer 500, a heat slug 600, and connection terminals 700.

The semiconductor chips 200, 200B, 200C, and 200D may be stacked in a cascade or stepped structure on the substrate 100. The semiconductor chip 200B may be disposed on the semiconductor chip 200, protruding or extending further in a first direction DR1. The semiconductor chip 200B may have a surface S11 and a surface S12 that are opposite to each other in a third direction DR3, with a DAF 300B attached to the surface S11. The chip pads CP5 and the dummy pad DP6 may be disposed on the surface S12. The semiconductor chip 200B may include a hotspot H4 defined in a predetermined region therein. The hotspot H4 may be connected to the dummy pad DP6 by the layer L6. The area where the hotspot H1 of the semiconductor chip 200 is located may vertically overlap with at least part of the semiconductor chip 200B, which is positioned above the semiconductor chip 200. Additionally, the area where the hotspot H4 of the semiconductor chip 200B is located may vertically overlap with at least part of the semiconductor chip 200C, which is positioned above the semiconductor chip 200B.

The chip pads CP5 may be electrically connected to the chip pads CP1 of the semiconductor chip 200 through the wires W5. Through this, the semiconductor chip 200B may transmit and receive electrical signals with the semiconductor chip 200 and the substrate 100. The pillar P6 may be disposed on the dummy pad DP6. The pillar P6 may extend longitudinally in the third direction DR3. A recess R6 may be formed on the upper part of the pillar P6 and may have a shape that is recessed inwardly from a surface S6 of the mold film 400. At least part of the thermal interface material layer 500 may fill the recess R6.

The semiconductor chip 200C may be disposed on the semiconductor chip 200B, protruding or extending further in the first direction DR1. The semiconductor chip 200C may have a surface S13 and a surface S14 that are opposite to each other in the third direction DR3, with a DAF 300C attached to the surface S13. The chip pads CP6 and the dummy pad DP7 may be disposed on the surface S14. The semiconductor chip 200C may include a hotspot H5 defined in a predetermined region therein. The hotspot H5 may be connected to the dummy pad DP7 by the layer L7. The area where the hotspot H5 of the semiconductor chip 200C is located may vertically overlap with at least part of the semiconductor chip 200D, which is positioned above the semiconductor chip 200C.

The chip pads CP6 may be electrically connected to the chip pads CP5 of the semiconductor chip 200B through the wires W6. Through this, the semiconductor chip 200C may transmit and receive electrical signals with the semiconductor chip 200B and the substrate 100. The pillar P7 may be disposed on the dummy pad DP7. The pillar P7 may extend longitudinally in the third direction DR3. A recess R7 having a shape that is recessed inwardly from the surface S6 of the mold film 400 may be formed on the upper part of the pillar P7. At least part of the thermal interface material layer 500 may fill the recess R7.

The semiconductor chip 200D may be disposed on the semiconductor chip 200C, protruding or extending further in the first direction DR1. The semiconductor chip 200D may have a surface S15 and a surface S16 that are opposite to each other in the third direction DR3, with a DAF 300D attached to the surface S15. The chip pads CP7 and the dummy pad DP8 may be disposed on the surface S16. The semiconductor chip 200D may include a hotspot H6 defined in a predetermined region therein. The hotspot H6 may be connected to the dummy pad DP8 by the layer L8.

The chip pads CP7 may be electrically connected to the chip pads CP6 of the semiconductor chip 200C through the wires W7. Through this, the semiconductor chip 200D may transmit and receive electrical signals with the semiconductor chip 200C and the substrate 100. The pillar P8 may be disposed on the dummy pad DP8. The pillar P8 may extend longitudinally in the third direction DR3. A recess R8 having a shape that is recessed inwardly from the surface S6 of the mold film 400 may be formed on the upper part of the pillar P8. At least part of the thermal interface material layer 500 may fill the recess R8.

The semiconductor chips 200B, 200C, and 200D may be non-volatile memory chips or volatile memory chips, such as PRAMs, RRAMs, MRAMs, DRAMs, or flash memory devices, but the present disclosure is not limited thereto. Alternatively, the semiconductor chips 200B, 200C, and 200D may be logic chips.

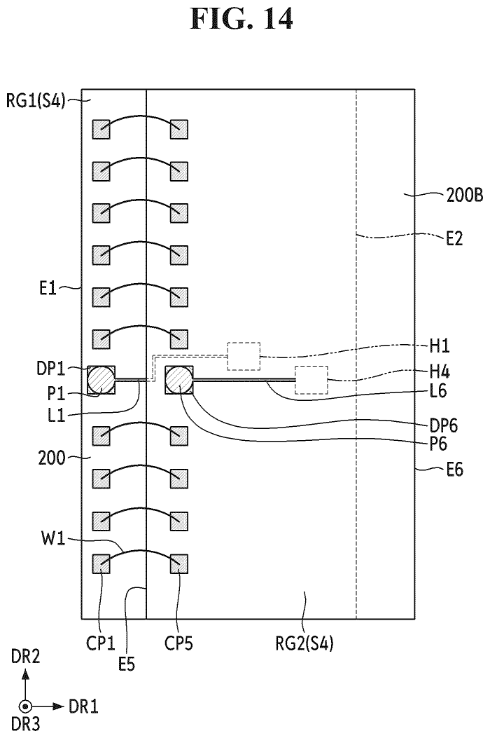

In a stacked semiconductor chip structure with a cascade configuration as illustrated in FIG. 12, the area where the hotspot within a lower semiconductor chip is located may vertically overlap with at least part of an upper semiconductor chip. This will be described below in further detail with reference to FIG. 14.

As illustrated in FIG. 12, the dummy pads DP1, DP6, DP7, and DP8 of the semiconductor chips 200, 200B, 200C, and 200D may be disposed adjacent to the edges of the respective semiconductor chips. Since the dummy pads DP1, DP6, DP7, and DP8 are formed during a wafer fabrication stage rather than during a package fabrication stage, if the dummy pads DP1, DP6, DP7, and DP8 are formed in the same location for their respective semiconductor chips, the wafer manufacturing yield can be improved.

FIG. 12 illustrates that the substrate 100 is electrically connected to the semiconductor chip 200 through the wires W1, the semiconductor chip 200 is electrically connected to the semiconductor chip 200B through the wires W5, the semiconductor chip 200B is electrically connected to the semiconductor chip 200C through the wires W6, and the semiconductor chip 200C is electrically connected to the semiconductor chip 200D through the wires W7, but the present disclosure is not limited thereto. Alternatively, the semiconductor chips 200B, 200C, and 200D may be directly connected to the substrate pads 106A on the substrate 100 through wires.

The recesses R1, R6, R7, and R8, which are recessed inwardly from the surface S6 of the mold film 400, may be spaced apart from one another in a planar perspective. In FIG. 12, the recesses R1, R6, R7, and R8 are illustrated as having the same width, but the present disclosure is not limited thereto. Alternatively, in some embodiments, the recesses R1, R6, R7, and R8 may be configured to have different widths.

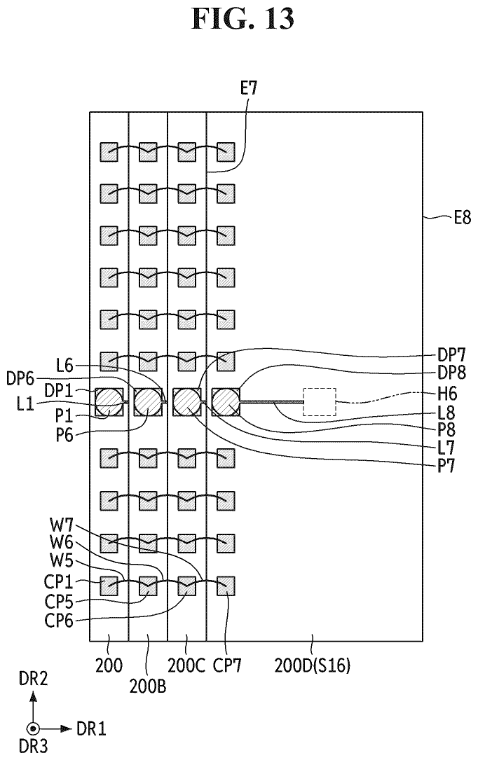

FIG. 13 is a schematic diagram illustrating part of the semiconductor package of FIG. 12.

Referring to FIG. 13, the semiconductor chips 200, 200B, 200C, and 200D may each have two edges that extend longitudinally in the second direction DR2 and are spaced apart from each other in the first direction DR1. The chip pads CP1, the chip pads CP5, the chip pads CP6, and the chip pads CP7 may be arranged side-by-side along the edges of their respective semiconductor chips that are closer to the opposite direction of the first direction DR1. The dummy pads DP1, DP6, DP7, and DP8 may be disposed between a pair of adjacent chip pads CP1, a pair of adjacent chip pads CP5, a pair of adjacent chip pads CP6, and a pair of adjacent chip pads CP7, respectively, in the second direction DR2.

For example, the surface S16, which corresponds to the upper surface of the uppermost semiconductor chip 200D, may have two edges E7 and E8 that extend longitudinally in the second direction DR2 and are spaced apart from each other in the first direction DR1. The chip pads CP7 may be arranged side-by-side along the edge E7, and the dummy pad DP8 may be disposed between the chip pads CP7, on the surface S16 of the semiconductor chip 200D. Additionally, the dummy pads DP1, DP6, DP7, and DP8 may be arranged side-by-side in the first direction DR1.

FIG. 14 is a schematic diagram illustrating part of the semiconductor package of FIG. 12.

FIG. 14 illustrates only the semiconductor chips 200 and 200B, but the following description may be equally applicable to the area between the semiconductor chips 200B and 200C, as well as the area between the semiconductor chips 200C and 200D.

Referring to FIGS. 12 and 14, the surface S4 of the semiconductor chip 200 may include a region RG1 and a region RG2. The regions RG1 and RG2 may be distinct from each other. The region RG1 may be a region of the semiconductor chip 200 that is exposed by the semiconductor chip 200B on the semiconductor chip 200, and the region RG2 may be a region that vertically overlaps with the semiconductor chip 200B. In this case, the hotspot H1 may be located within the semiconductor chip 200, in an area that vertically overlaps with the region RG2. In other words, the hotspot H1 within the semiconductor chip 200 may be obscured by the semiconductor chip 200B. Similarly, although not illustrated in FIG. 14, the hotspot H4 within the semiconductor chip 200B may be obscured by the semiconductor chip 200C.

Thus, when the semiconductor package 3000 includes multiple semiconductor chips 200, 200B, 200C, and 200D that are stacked in a cascade structure, the hotspot within a lower semiconductor chip, for example, the hotspot H1, may be obscured by the corresponding upper semiconductor chip, i.e., the semiconductor chip 200B, rather than being exposed to the outside. As a result, heat dissipation may not be as efficient as when the hotspot H1 is exposed. According to the present disclosure, the hotspot H1 obscured by the semiconductor chip 200B may be connected to the thermal interface material layer 500 and the heat slug 600 through a heat dissipation structure (e.g., layers, dummy pads, and pillars). Accordingly, the heat generated at the hotspot H1 can be effectively dissipated to the outside of the semiconductor package 3000.

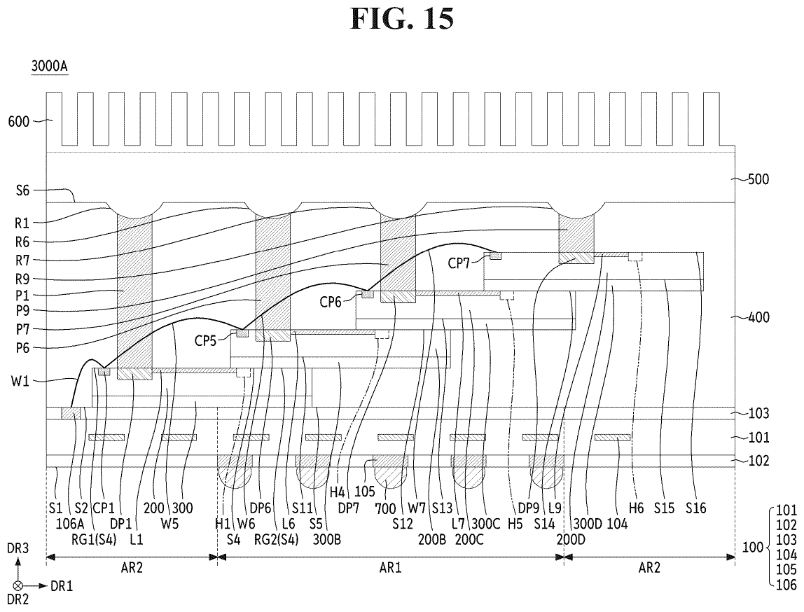

FIG. 15 is a diagram illustrating a semiconductor package according to some embodiments.

Referring to FIG. 15, in a semiconductor package 3000A, a dummy pad DP9 may be disposed on a surface S16 of a semiconductor chip 200D, and a pillar P9 may be disposed on the dummy pad DP9. The dummy pad DP9 may be connected to the hotspot H6 through a layer L9, and a recess R9 having a shape that is recessed inwardly from a surface S6 of a mold film 400 may be formed on the upper part of the pillar P9. At least part of a thermal interface material layer 500 may fill the recess R9.

Whereas the dummy pad DP8 of FIG. 12 is disposed adjacent to the edge of the surface S16 of the semiconductor chip 200D, the dummy pad DP9 of FIG. 15 may be disposed closer to the center of a semiconductor chip 200, compared to the dummy pad DP8 of FIG. 12. That is, the dummy pad DP9 of FIG. 15 may be disposed closer than the dummy pad DP8 of FIG. 12 to a hotspot H6. As a result, the length, in a first direction DR1, of the layer L9 in the semiconductor chip 200D of FIG. 15 may be less than the length, in the first direction DR1, of the layer L8 in the semiconductor chip 200D of FIG. 12.

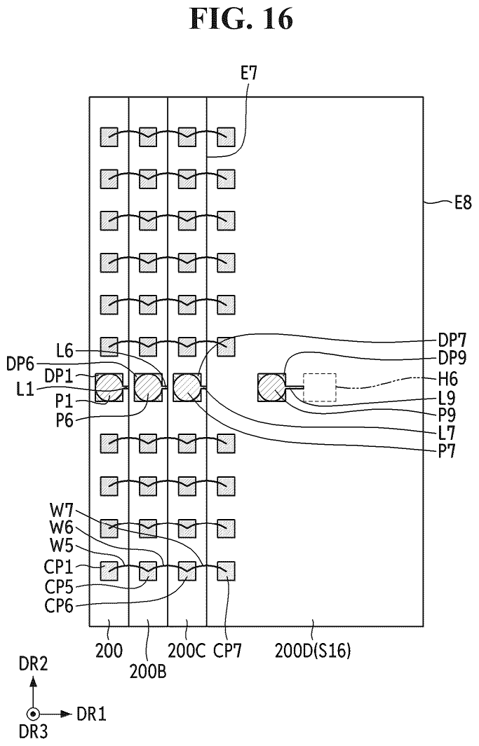

FIG. 16 is a schematic diagram illustrating part of the semiconductor package of FIG. 15.

Referring to FIG. 16, in a plurality of semiconductor chips 200, 200B, 200C, and 200D that are stacked in a cascade structure, dummy pads in all the semiconductor chips except for the uppermost semiconductor chip 200D, i.e., dummy pads DP1, DP6, and DP7, may be disposed between a pair of adjacent chip pads CP1, a pair of adjacent chip pads CP5, and a pair of adjacent chip pads CP6, respectively, in a second direction DR2. That is, the dummy pads DP1, DP6, and DP7 may be disposed adjacent to the edges of the upper surfaces of the respective semiconductor chips.

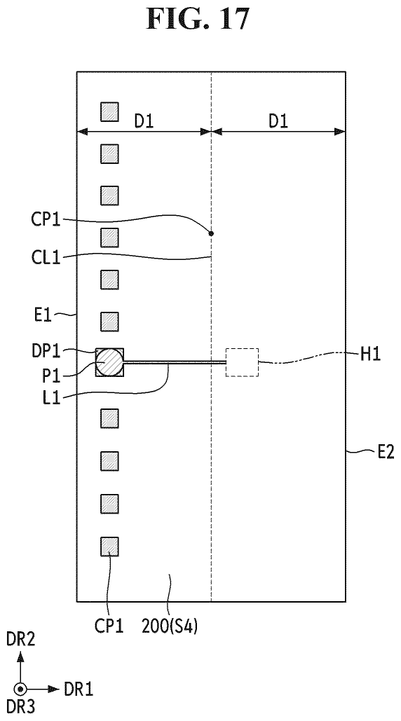

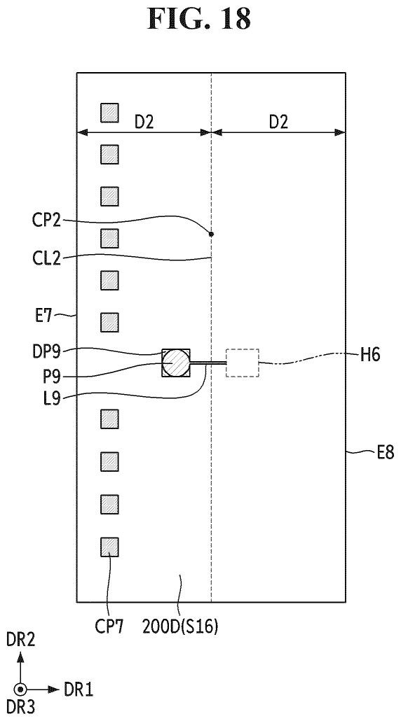

On the other hand, in the case of the uppermost semiconductor chip 200D, the dummy pad DP9 may be disposed closer to the center of the upper surface of the semiconductor chip 200D than to the edge of the upper surface of the semiconductor chip 200D, to become closer to the hotspot H6. This will hereinafter be explained in further detail with reference to FIGS. 17 and 18.

FIGS. 17 and 18 are schematic diagrams illustrating part of the semiconductor package of FIG. 15.

The following description assumes that, as illustrated in FIGS. 17 and 18, hotspots H1, H4, and H5 and the hotspot H6 are disposed close to the centers of the respective semiconductor chips.

FIG. 17 is a top view illustrating only part of the configuration of the lowermost semiconductor chip 200 in the semiconductor package 3000A where the semiconductor chips 200, 200B, 200C, and 200D are stacked in a cascade structure. The following description may be equally applicable to all the semiconductor chips 200, 200B, 200C, and 200D except for the uppermost semiconductor chip 200D.

A surface S4 of the semiconductor chip 200 may include a central line CLI extending longitudinally in the second direction DR2. The central line CLI may be equidistant from edges E1 and E2 of the surface S4 by a distance D1. A central point CP1 of the semiconductor chip 200 may be an arbitrary point on the central line CL1. The dummy pad DP1, disposed on the surface S4 of the semiconductor chip 200, may be disposed closer to the edge E1 than to the central point CP1. For example, as illustrated in FIG. 17, the dummy pad DP1 may be disposed between the chip pads CP1, which are arranged side-by-side along the second direction DR2.

FIG. 18 is a top view schematically illustrating only part of the configuration of the uppermost semiconductor chip 200D in the semiconductor package 3000A where the semiconductor chips 200, 200B, 200C, and 200D are stacked in a cascade structure.

The surface S16 of the semiconductor chip 200D may include a central line CL2 extending longitudinally in the second direction DR2. The central line CL2 may be equidistant from the edges E7 and E8 of the surface S16 by a distance D2. A central point CP2 of the semiconductor chip 200D may be an arbitrary point on the central line CL2. The dummy pad DP9, disposed on the surface S16 of the semiconductor chip 200D, may be disposed closer to the central point CP2 than to the edge E7 or E8.

According to the present disclosure, the closer the dummy pad on a semiconductor chip and the pillar on the dummy pad are disposed to the hotspot within the semiconductor chip, the better the heat dissipation characteristics. However, as illustrated in FIG. 15, in the semiconductor package 3000A where the semiconductor chips 200, 200B, 200C, and 200D are stacked in a cascade structure, the lower semiconductor chips, i.e., the semiconductor chips 200, 200B, and 200C, need to have other semiconductor chips stacked thereon. Thus, even if hotspots are located at the centers of the semiconductor chips 200, 200B, and 200C, dummy pads and pillars cannot be arranged close to the hotspots due to space constraints, and need to be positioned near the edges of the semiconductor chips 200, 200B, and 200C. However, since no semiconductor chip is disposed on the uppermost semiconductor chip, i.e., the semiconductor chip 200D, the dummy pad DP9 and the pillar P9 can be arranged close to the hotspot H6 without such constraints.

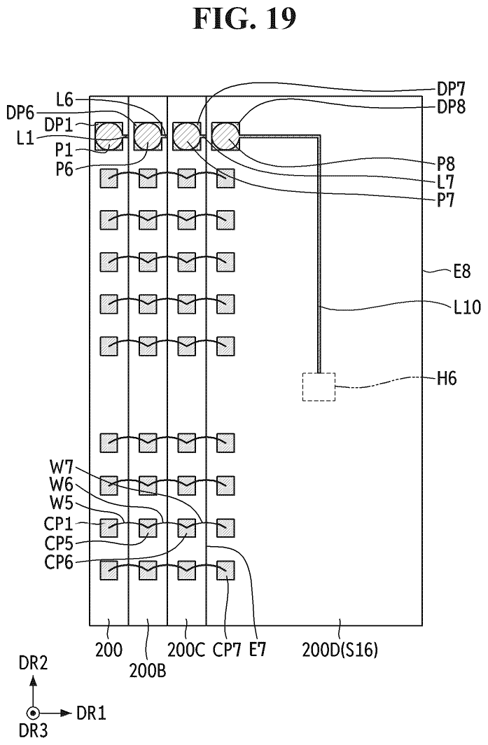

FIG. 19 is a diagram illustrating a semiconductor package according to some embodiments.

Referring to FIG. 19, unlike in the embodiment of FIG. 13, dummy pads DP1, DP6, DP7, and DP8 may be disposed at, and spaced apart from, the ends of the arrays of chip pads CP1, chip pads CP5, chip pads CP6, and chip pads CP7, respectively, that are each arranged side-by-side in a second direction DR2. For example, in the case of an uppermost semiconductor chip 200D, the dummy pad DP8 may be disposed in the second direction DR2 at a distance from the chip pad CP7 at the far end of the array of the chip pads CP7 that are arranged side-by-side in the second direction DR2.

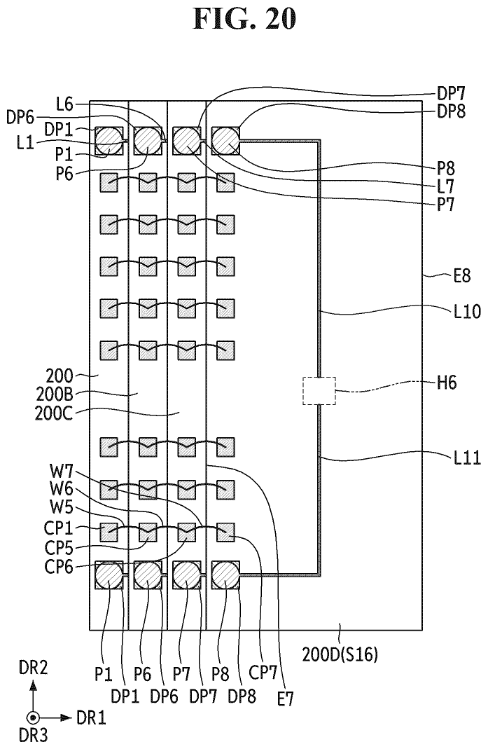

FIG. 20 is a diagram illustrating a semiconductor package according to some embodiments.

Referring to FIG. 20, unlike in the embodiments of FIGS. 13 and 19, two or more dummy pads and pillars may be disposed on the upper surface of each of semiconductor chips 200, 200B, 200C, and 200D. For example, in the case of the uppermost semiconductor chip, i.e., the semiconductor chip 200D, one of two dummy pads DP8 may be disposed in a second direction DR2 at a distance from the chip pad CP7 at the far end of the array of chip pads CP7 that are arranged side-by-side in the second direction DR2, while the other dummy pad DP8 may be disposed in the opposite direction of the second direction DR2 at a distance from the chip pad CP7 at the far end of the array of chip pads CP7 that are arranged side-by-side in the opposite direction of the second direction DR2. One of the dummy pads DP8 may be connected to the hotspot H6 through a layer L10 and the other one of the dummy pads DP8 may be connected to the hotspot H6 through a layer L11.

In this manner, two or more conduction-based heat dissipation structures (e.g., layers, dummy pads, pillars, recesses, etc.) may be formed for the hotspot defined in a predetermined region within each of the semiconductor chips 200, 200B, 200C, and 200D, allowing the heat generated at the hotspots to be dissipated more effectively.

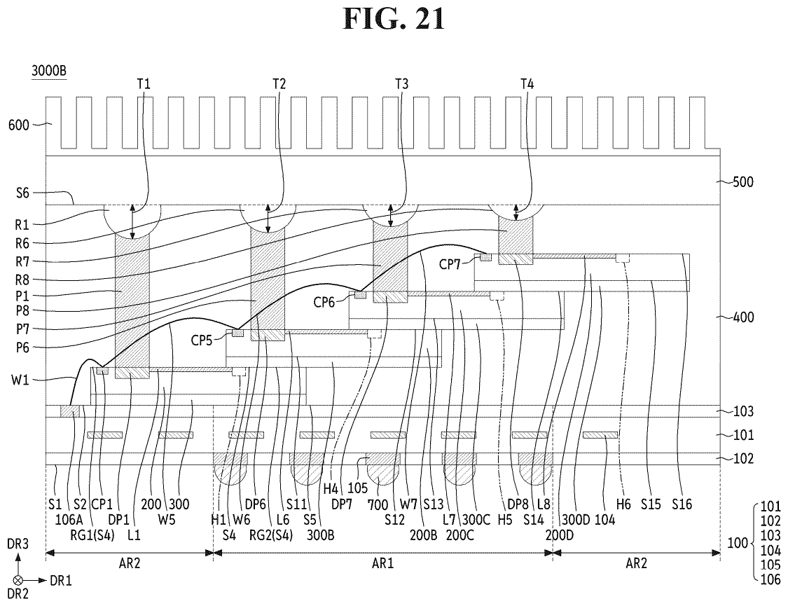

FIG. 21 is a diagram illustrating a semiconductor package according to some embodiments.

Referring to FIG. 21, unlike in the embodiment of FIG. 12, the widths or thicknesses of recesses R1, R6, R7, and R8 that are recessed inwardly from a surface S6 of a mold film 400 may differ. For example, a width T4 of the recess R8 corresponding to an uppermost semiconductor chip, i.e., a semiconductor chip 200D, may be smaller than a width T3 of the recess R7 corresponding to a semiconductor chip 200C disposed below the semiconductor chip 200D, the width T3 of the recess R7 may be smaller than a width T2 of the recess R6 corresponding to a semiconductor chip 200B disposed below the semiconductor chip 200C, and a width Tl of the recess R1 corresponding to a lowermost semiconductor chip, i.e., a semiconductor device 200, may be the smallest.

The recesses R1, R6, R7, and R8 are formed by arranging pillars P1, P6, P7, and P8, respectively, on dummy pads DP1, DP6, DP7, and DP8, respectively, covering the pillars P1, P6, P7, and P8 with the mold film 400, and then drilling to remove the upper parts of the pillars P1, P6, P7, and P8 and the upper part of the mold film 400 covering the pillars P1, P6, P7, and P8. Thus, if the mold film 400 is drilled beyond a predetermined threshold, the semiconductor chips 200, 200B, 200C, and 200D may not be sufficiently protected by the mold film 400, leading to a reliability issue in a semiconductor package 3000B.

The thickness, in a third direction DR3, of the mold film 400 covering the upper surfaces of the semiconductor chips 200, 200B, 200C, and 200D is referred to as a mold gap. If the mold gap is not sufficiently secured, the rate of defects in the semiconductor package 3000B, such as cracks in the semiconductor chips 200, 200B, 200C, and 200D, may increase.

Meanwhile, to effectively dissipate the heat from hotspots H1, H4, H5, and H6 to the outside of the semiconductor package 3000B, the upper parts of the pillars P1, P6, P7, and P8 should be sufficiently drilled to expose the upper surfaces of the pillars P1, P6, P7, and P8 and increase the contact areas of the pillars P1, P6, P7, and P8 and a thermal interface material layer 500. As illustrated in FIG. 21, since the lowermost semiconductor chip 200 has a sufficient mold gap compared to the uppermost semiconductor chip 200D, the pillar P1 can be sufficiently drilled to have its upper surface exposed and have an increased contact area with the thermal interface material layer 500, thereby effectively dissipating the heat from the hotspot H1. However, since the mold gap may not be sufficiently secured for each semiconductor chip positioned higher, the respective pillars may be relatively less drilled to ensure the reliability of the mold film 400.

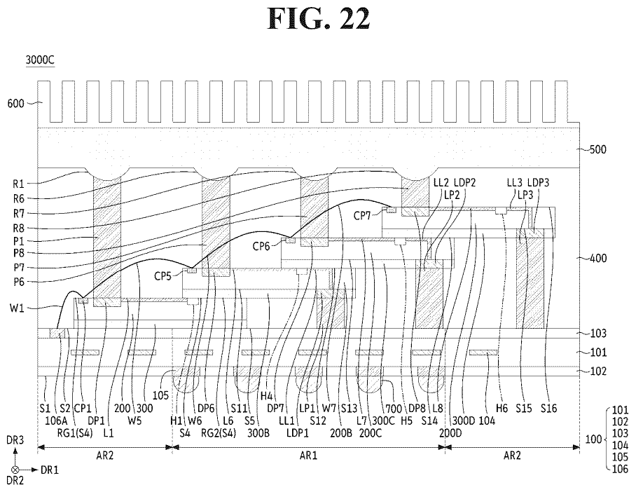

FIG. 22 is a diagram illustrating a semiconductor package according to some embodiments.

Referring to FIG. 22, in a semiconductor package 3000C, a semiconductor chip 200B may further include a lower dummy pad LDP1 and a lower layer LL1. The lower dummy pad LDP1 may be disposed on a surface S11, which corresponds to the lower surface of the semiconductor chip 200B. The lower dummy pad LDP1 may be disposed in an area of the surface S11 of the semiconductor chip 200B that is not covered by a DAF 300B, and thus, the lower surface of the lower dummy pad LDP1 may be exposed. The lower layer LL1 may connect a hotspot H4 and the lower dummy pad LDP1. The semiconductor package 3000C may further include a lower pillar LP1, which is disposed on the lower surface of the lower dummy pad LDP1. The lower pillar LP1 may extend in a third direction DR3 from the lower surface of the lower dummy pad LDP1 to a surface S2 of a substrate 100.

A semiconductor chip 200C may further include a lower dummy pad LDP2 and a lower layer LL2. The lower dummy pad LDP2 may be disposed on a lower surface S13 of the semiconductor chip 200C. The lower dummy pad LDP2 may be disposed in an area of the surface S13 of the semiconductor chip 200C that is not covered by a DAF 300C, and thus, the lower surface of the lower dummy pad LDP2 may be exposed. The lower layer LL2 may connect a hotspot H5 and the lower dummy pad LDP2. The semiconductor package 3000C may further include a lower pillar LP2, which is disposed on the lower surface of the lower dummy pad LDP2. The lower pillar LP2 may extend in the third direction DR3 from the lower surface of the lower dummy pad LDP2 to the surface S2 of the substrate 100.

A semiconductor chip 200D may further include a lower dummy pad LDP3 and a lower layer LL3. The lower dummy pad LDP3 may be disposed on a lower surface S15 of the semiconductor chip 200D. The lower dummy pad LDP3 may be disposed in an area of the surface S15 of the semiconductor chip 200D that is not covered by a DAF 300D, and thus, the lower surface of the lower dummy pad LDP3 may be exposed. The lower layer LL3 may connect a hotspot H6 and the lower dummy pad LDP3. The semiconductor package 3000C may further include a lower pillar LP3, which is disposed on the lower surface of the lower dummy pad LDP3. The lower pillar LP3 may extend in the third direction DR3 from the lower surface of the lower dummy pad LDP3 to the surface S2 of the substrate 100.

In this case, the lower pillars LP1, LP2, and LP3 may not be electrically connected to a wiring layer 104 of the substrate 100 but may be physically connected only to the substrate 100 for heat dissipation.

Heat generated at the hotspot within each semiconductor chip can be dissipated to the outside of the semiconductor package 3000C not only through an upper dummy pad and an upper pillar disposed on the upper surface of the corresponding semiconductor chip but also through a lower dummy pad and a lower pillar additionally disposed on the lower surface of the corresponding semiconductor chip.

The dummy pads disposed on the upper surfaces of the semiconductor chips 200, 200B, 200C, and 200D may be defined as upper dummy pads DP1, DP6, DP7, and DP8, respectively, and the dummy pads disposed on the lower surfaces of the semiconductor chips 200B, 200C, and 200D may be defined as the lower dummy pads LDP1, LDP2, and LDP3, respectively. Additionally, the pillars disposed on the upper dummy pads DP1, DP6, DP7, and DP8 may be defined as upper pillars P1, P6, P7, and P8, respectively, and the pillars disposed on the lower dummy pads LDP1, LDP2, and LDP3 may be defined as the lower pillars LP1, LP2, and LP3, respectively.

According to the present disclosure, since heat dissipation structures are arranged on both the upper and lower surfaces of each semiconductor chip, the heat dissipation characteristics of the semiconductor package 3000C can be improved.

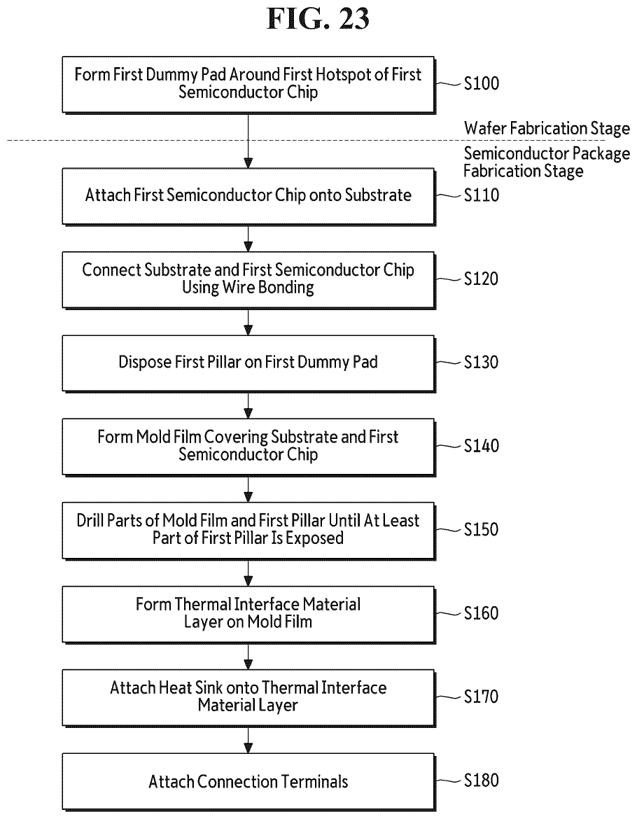

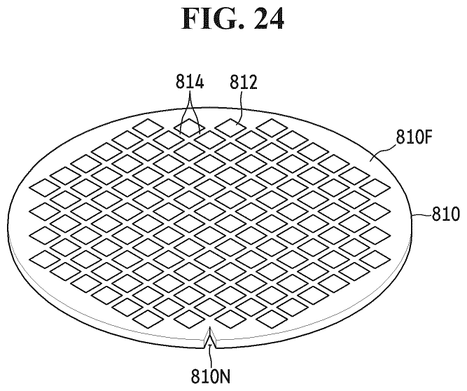

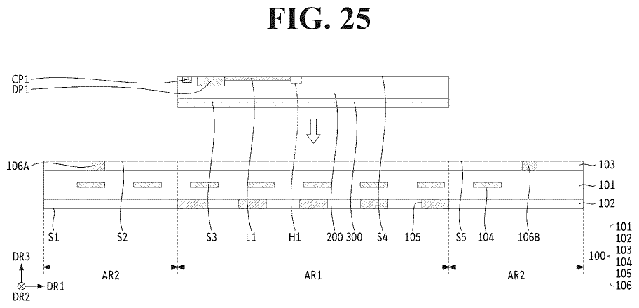

FIG. 23 is a flowchart illustrating a method of manufacturing a semiconductor package according to some embodiments. FIGS. 24 through 31 are diagrams illustrating the method of manufacturing a semiconductor package according to some embodiments. The method of manufacturing a semiconductor package according to some embodiments will hereinafter be described with reference to FIGS. 23 through 31.

Referring to FIGS. 23 through 25, a dummy pad DP1 may be formed in the area around or surrounding a hotspot H1 within a semiconductor chip 200 (S100). The dummy pad DP1 may be disposed spaced apart from the hotspot H1 within the semiconductor chip 200, and the dummy pad DP1 and the hotspot H1 may be connected by a layer L1 within the semiconductor chip 200. Additionally, chip pads CP1 may be formed on a surface S4 of the semiconductor chip 200. In this manner, the process of forming the dummy pad DP1 on a surface S4 of the semiconductor chip 200 to dissipate the heat generated by the hotspot H1 may be performed in advance during a wafer fabrication stage.

A wafer 810 may be a semiconductor wafer and may have a circular shape in a planar perspective. The wafer 810 may have a notch 810N that serves as an alignment marker for the wafer 810. The wafer 810 may include silicon (Si). Alternatively, the wafer 810 may include a semiconductor element such as germanium (Ge) or a compound semiconductor such as silicon carbide (SiC), gallium arsenide (GaAs), indium arsenide (InAs), or indium phosphide (InP). Alternatively, the wafer 810 may have a silicon-on-insulator (SOI) structure.

In some embodiments, the wafer 810 may include wells doped with impurities, which are conductive regions, or structures doped with impurities. Additionally, the wafer 810 may have various device isolation structures, such as a shallow trench isolation (STI) structure. The wafer 810 may have a diameter of approximately 12 inches, and an Si wafer may be used as the wafer 810. Alternatively, the wafer 810 may have a diameter smaller or larger than 12 inches and may be formed of a material other than Si.

The wafer 810 may have an active surface 810F and an inactive surface that are opposite to each other in a vertical direction. A semiconductor device layer may be formed on the active surface 810F of the wafer 810. The semiconductor device layer may include an insulating layer and/or a conductive layer provided on the active surface 810F of the wafer 810. Additionally, the semiconductor device layer may include semiconductor devices and a metal interconnect structure.

The wafer 810 may include integrated circuit regions 812 and cutting regions 814 that separate the integrated circuit regions 812. The cutting regions 814 may also be referred to as scribe lines. The cutting regions 814 may have a linear shape with a uniform width. Each of the integrated circuit regions 812 may be surrounded by the cutting regions 814 in a planar perspective. Through a cutting process (e.g., a dicing process) performed along the cutting regions 814, the wafer 810 and various types of material layers formed on the wafer 810 may be cut, and the integrated circuit regions 812 may be separated into multiple semiconductor chips.

Accordingly, each of the separated semiconductor chips may correspond to any one of the semiconductor chips described above with reference to FIGS. 1 through 22. That is, each of the integrated circuit regions 812 may correspond to one semiconductor chip, and during the wafer fabrication stage, at least one hotspot may be included within each of the integrated circuit regions 812. A dummy pad and a layer connecting the dummy pad and the hotspot may be formed within each of the integrated circuit regions 812.

Thereafter, the semiconductor chip 200 may be attached to a substrate 100 (S110). The semiconductor chip 200 may be one of the semiconductor chips separated from the wafer 810 of FIG. 24. The semiconductor chip 200 may be attached to the substrate 100 via a DAF 300 attached to its surface S3.

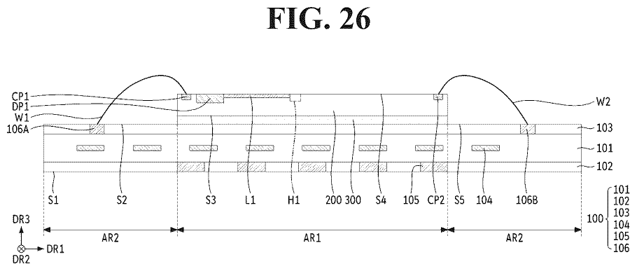

Thereafter, referring to FIGS. 23 and 26, the substrate 100 and the semiconductor chip 200 may be connected by wire bonding (S120). For example, chip pads CP1 and substrate pads 106A may be electrically connected to each other using wires W1, and chip pads CP2 and substrate pads 106B may be electrically connected to each other using wires W2.

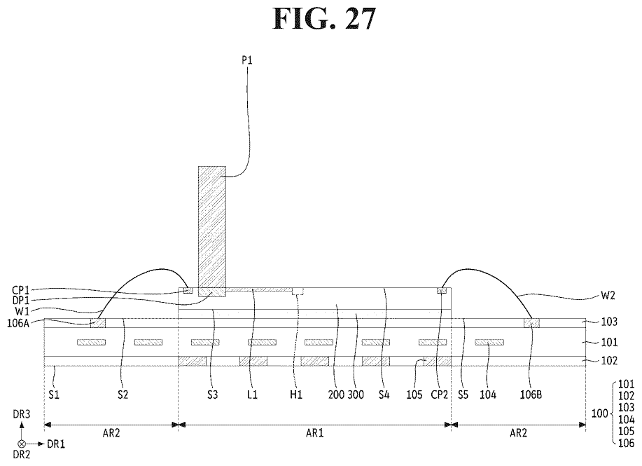

Thereafter, referring to FIGS. 23 and 27, a pillar P1 may be disposed on a dummy pad DP1 (S130). The lower surface of the pillar P1 may be in contact with the upper surface of the dummy pad DP1.

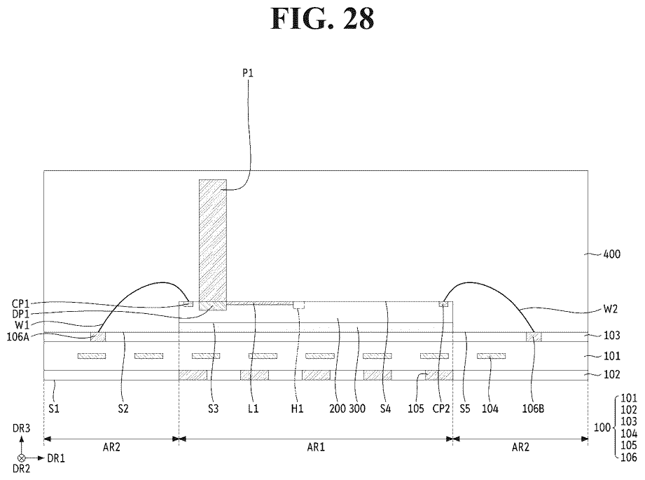

Thereafter, referring to FIGS. 23 and 28, a mold film 400 may be formed on the substrate 100 (S140). The mold film 400 may cover at least parts of the sides and upper surface of the semiconductor chip 200, at least parts of the sides and upper surface of the pillar P1, at least parts of the wires W1 and the wires W2, and at least part of the upper surface of the substrate 100.

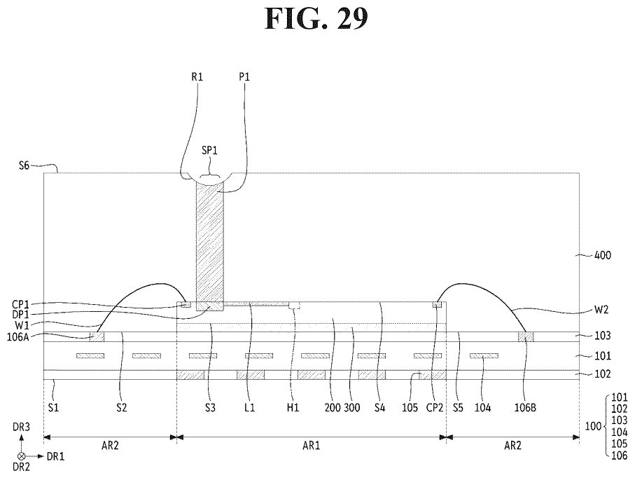

Thereafter, referring to FIGS. 23 and 29, the mold film 400 and at least part of the pillar P1 may be drilled so that at least part of the pillar P1 may be exposed (S150). Through drilling, a recess R1 having a shape that is recessed inwardly from a surface S6 of the mold film 400 may be formed. A space SP1, defined between the area of the surface S6 of the mold film 400 where the recess R1 is formed and an interface I1 of the recess R1 where the mold film 400 and the pillar P1 are in contact, may be formed through drilling.

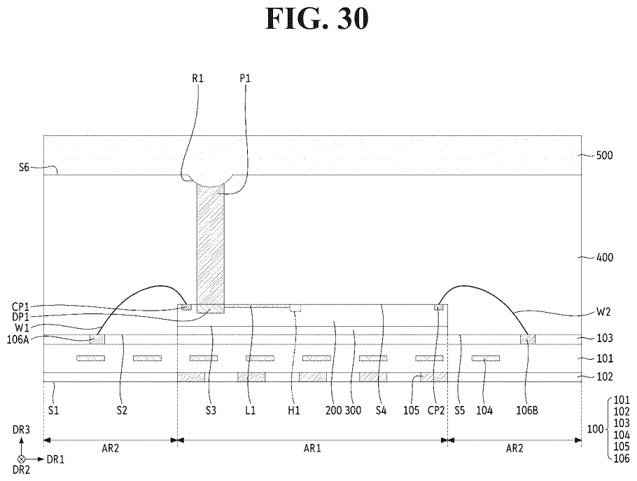

Thereafter, referring to FIGS. 23 and 30, a thermal interface material layer 500 may be formed on the mold film 400 (S160). At least part of the thermal interface material layer 500 may fill the space SP1.

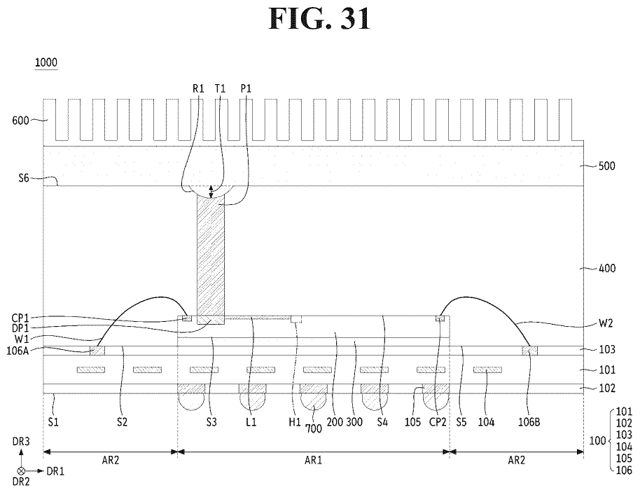

Thereafter, referring to FIGS. 23 and 31, a heat slug 600 may be attached to the thermal interface material layer 500 (S170), and connection terminals 700 may be attached to substrate pads 105 (S180).

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the example embodiments as described above are not restrictive but illustrative in all respects.

What is claimed is:

1. A semiconductor package comprising:
a substrate including a first surface and a second surface that are opposite to each other in a first direction, and a first substrate pad on the second surface;
a first semiconductor chip on the second surface and including a third surface facing the second surface, a fourth surface opposite to the third surface in the first direction, a first hotspot defined in a predetermined region within the first semiconductor chip, and a first chip pad on the fourth surface;
a first wire connecting the first substrate pad and the first chip pad;
a first dummy pad on the fourth surface and spaced apart from the first hotspot;
a first layer connecting the first hotspot and the first dummy pad;
a first pillar on the first dummy pad and extending in the first direction;
a mold film on the substrate, covering at least part of the first semiconductor chip, at least part of the first pillar, and at least part of the first wire, and including a fifth surface facing the second surface and a sixth surface opposite to the fifth surface in the first direction;
a thermal interface material layer on the mold film; and
a heat slug on the thermal interface material layer,
wherein
the mold film includes a first recess recessed inwardly from the sixth surface of the mold film, and
at least part of the thermal interface material layer fills a first space defined between an area of the sixth surface of the mold film where the first recess is formed and an interface of the first recess where the mold film and the first pillar are in contact.

2. The semiconductor package of claim 1, wherein:
the fourth surface includes a first edge and a second edge that extend in a second direction intersecting the first direction and are spaced apart from each other in a third direction intersecting both the first and second directions, and a third edge and a fourth edge that extend in the third direction and are spaced apart from each other in the second direction,
the first chip pad comprises a plurality of first chip pads,
at least some of the plurality of first chip pads are arranged side-by-side along the first edge, and
the semiconductor package further includes a plurality of second chip pads arranged side-by-side along the second edge.

3. The semiconductor package of claim 2, wherein the first dummy pad is disposed closer to the second edge than the plurality of first chip pads arranged along the first edge.

4. The semiconductor package of claim 2, wherein the first dummy pad is disposed along the third edge or the fourth edge.

5. The semiconductor package of claim 1, further comprising:
a second dummy pad on the fourth surface and spaced apart from the first hotspot;
a second layer connecting the first hotspot and the second dummy pad; and
a second pillar on the second dummy pad and extending in the first direction,
wherein
the mold film further includes a second recess recessed inwardly from the sixth surface of the mold film, and
at least part of the thermal interface material layer fills a second space defined between an area of the sixth surface of the mold film where the second recess is formed and an interface of the second recess where the mold film and the second pillar are in contact.

6. The semiconductor package of claim 1, wherein
the first semiconductor chip further includes a second hotspot defined in a different region from a region where the first hotspot is defined,
the semiconductor package further includes a second dummy pad on the fourth surface and spaced apart from the second hotspot, a second layer connecting the first hotspot and the second dummy pad, and a second pillar on the second dummy pad and extending in the first direction,
the mold film further includes a second recess recessed inwardly from the sixth surface of the mold film, and
at least part of the thermal interface material layer fills a second space defined between an interface of the second recess where the mold film and the second pillar are in contact and an area of the sixth surface of the mold film where the second recess is formed.

7. The semiconductor package of claim 1, wherein:
the substrate further includes a second substrate pad on the second surface, and
the semiconductor package further comprises:
a second semiconductor chip on the second surface, spaced apart from the first semiconductor chip, and including a seventh surface facing the second surface, an eighth surface opposite to the seventh surface in the first direction, a second hotspot defined in a predetermined region, and a second chip pad on the eighth surface;
a second wire connecting the second substrate pad and the second chip pad;
a second dummy pad on the eighth surface and spaced apart from the second hotspot;
a second layer connecting the second hotspot and the second dummy pad; and
a second pillar on the second dummy pad and extending in the first direction.

8. The semiconductor package of claim 7, wherein
the mold film further includes a second recess recessed inwardly from the sixth surface of the mold film, and
at least part of the thermal interface material layer fills a second space defined between an interface of the second recess, where the mold film and the second pillar are in contact, and an area of the sixth surface of the mold film where the second recess is formed.

9. The semiconductor package of claim 7, wherein
the first layer is within the first semiconductor chip, and
the second layer is within the second semiconductor chip.

10. The semiconductor package of claim 7, further comprising:
a connection terminal attached to the first surface,
wherein at least part of an area on the second surface where the first semiconductor chip is disposed does not overlap in the first direction with an area on the first surface where the connection terminal is attached.

11. A semiconductor package comprising:
a substrate including a first surface and a second surface that are opposite to each other in a first direction, and a first substrate pad on the second surface;
a first semiconductor chip on the second surface and including a third surface facing the second surface, a fourth surface opposite to the third surface in the first direction, a first hotspot defined in a predetermined region within the first semiconductor chip, and a first chip pad on the fourth surface;
a first wire connecting the first substrate pad and the first chip pad;
a first dummy pad on the fourth surface and spaced apart from the first hotspot;
a first layer connecting the first hotspot and the first dummy pad;
a first pillar on the first dummy pad and extending in the first direction;
a mold film on the substrate, covering at least part of the first semiconductor chip, at least part of the first pillar, and at least part of the first wire, and including a fifth surface facing the second surface and a sixth surface opposite to the fifth surface in the first direction;
a thermal interface material layer on the mold film; and
a heat slug on the thermal interface material layer,
wherein
the thermal interface material layer includes a first material layer and a second material layer disposed at a lower level in the first direction than the first material layer,
the first material layer includes a seventh surface facing or corresponding to the sixth surface and an eighth surface opposite to the seventh surface in the first direction, and
the second material layer includes a first interface in contact with the mold film and the first pillar and a second interface in contact with the seventh surface of the first material layer.

12. The semiconductor package of claim 11, wherein
the first interface includes a first region, a second region, and a third region sequentially arranged in a second direction intersecting the first direction,
the first and third regions are in contact with the mold film, and
the second region is in contact with the first pillar.

13. The semiconductor package of claim 11, further comprising:
at least one second semiconductor chip on the fourth surface and including a fifth surface facing the fourth surface and a sixth surface opposite to the fifth surface in the first direction, a second hotspot defined in a predetermined region within the at least one second semiconductor chip, and a second chip pad on the sixth surface;
a second dummy pad on the sixth surface and spaced apart from the second hotspot;
a second layer connecting the second hotspot and the second dummy pad; and
a second pillar on the second dummy pad and extending in the first direction,
wherein the second material layer includes a third interface in contact with the mold film and the second pillar, and a fourth interface in contact with the seventh surface of the first material layer and spaced apart from the second interface.

14. The semiconductor package of claim 13, wherein a maximum length in the first direction from the second interface to the first interface is greater than a maximum length in the first direction from the fourth interface to the third interface.

15. The semiconductor package of claim 13, further comprising:
a second wire connecting the first and second chip pads,
wherein the mold film covers at least part of the second wire.

16. A semiconductor package comprising:
a substrate including a first surface and a second surface that are opposite to each other in a first direction, and a substrate pad on the second surface;
a first semiconductor chip on the second surface and including a third surface facing the second surface, a fourth surface opposite to the third surface in the first direction, a first hotspot defined in a predetermined region within the first semiconductor chip, and a first chip pad on the fourth surface;
a first upper dummy pad on the fourth surface and spaced apart from the first hotspot;
a first layer connecting the first hotspot and the first upper dummy pad;
a first upper pillar on the first upper dummy pad and extending in the first direction;
at least one second semiconductor chip on the fourth surface, the at least one second semiconductor chip including a fifth surface facing the fourth surface, a sixth surface opposite to the fifth surface in the first direction, a second hotspot defined in a predetermined region within the at least one second semiconductor chip, and a second chip pad on the sixth surface;
a second upper dummy pad on the sixth surface and spaced apart from the second hotspot;
a second layer connecting the second hotspot and the second upper dummy pad;
a second upper pillar on the second upper dummy pad and extending longitudinally in the first direction;
a lower dummy pad on the fifth surface and spaced apart from the second hotspot;
a third layer connecting the second hotspot and the lower dummy pad;
a lower pillar connected to the lower dummy pad and extending in the first direction to be connected to the substrate;
a mold film on the substrate, covering at least a part of the first semiconductor chip, the at least one second semiconductor chip, the first and second upper pillars, and the lower pillar, and including a seventh surface facing the second surface and an eighth surface opposite to the seventh surface in the first direction;
a thermal interface material layer on the mold film; and
a heat slug on the thermal interface material layer,
wherein
the mold film includes at least two recesses recessed inwardly from the seventh surface, and
at least part of the thermal interface material layer fills a first space defined between an area of the seventh surface of the mold film where a first recess, which corresponds to the first upper pillar, is formed and an interface of the first recess where the mold film and the first upper pillar are in contact, and fills a second space defined between an area of the seventh surface of the mold film where a second recess, which corresponds to the second upper pillar, is formed and an interface of the second recess where the mold film and the second upper pillar are in contact.

17. The semiconductor package of claim 16, wherein
the fourth surface includes a first region exposed by the at least one second semiconductor chip and a second region that overlaps with the at least one second semiconductor chip in the first direction and is distinct from the first region, and
the first hotspot is disposed within the first semiconductor chip, in a region that overlaps with the second region in the first direction.

18. The semiconductor package of claim 16, wherein
the fourth surface includes a first edge and a second edge that extend in a second direction intersecting the first direction,
the sixth surface includes a third edge and a fourth edge that extend in the second direction,
the first edge and the second edge are spaced apart from each other in a third direction intersecting the first direction and the second direction,
the third edge and the fourth edge are spaced apart from each other in the third direction,
the fourth surface includes a first central portion equidistant from the first edge and the second edge, and
the sixth surface includes a second central portion equidistant from the third edge and the fourth edge,
the first upper dummy pad is disposed on the fourth surface to be closer to the first edge than to the first central portion, and
the second upper dummy pad is disposed on the sixth surface to be closer to the second central portion than to the third edge.

19. The semiconductor package of claim 16, wherein
the fourth surface includes a first edge and a second edge that extend in a second direction intersecting the first direction,
the first edge and the second edge are spaced apart from each other in a third direction intersecting the first direction and the second direction,
the first chip pad comprises a plurality of first chip pads,
the plurality of first chip pads are arranged side-by-side along the first edge, and
the first upper dummy pad is disposed between adjacent ones of the plurality of first chip pads.

20. The semiconductor package of claim 16, wherein
the fourth surface includes a first edge and a second edge that extend in a second direction intersecting the first direction,
the first edge and the second edge are spaced apart from each other in a third direction intersecting both the first direction and the second direction,
the first chip pad comprises a plurality of first chip pads,
the plurality of first chip pads are arranged side-by-side along the first edge, and
the first upper dummy pad is disposed at one end of the plurality of first chip pads and spaced apart from the plurality of first chip pads in the second direction.
